(19) United States
(12) Patent Application Publication
(10) Pub. No.: US 2012/0235278 A1
(43) Pub. Date: Sep. 20, 2012

(54) SEMICONDUCTOR INTEGRATED CIRCUIT DEVICE, METHOD OF MANUFACTURING THE SAME, AND ELECTRONIC SYSTEM USING THE SAME

(75) Inventors: Hisao Shigihara, Kanagawa (JP); Hiromi Shigihara, Kanagawa (JP); Akira Yajima, Kanagawa (JP)

(73) Assignee: RENESAS ELECTRONICS CORPORATION

(21) Appl. No.: 13/406,356

(22) Filed: Feb. 27, 2012

(30) Foreign Application Priority Data
Mar. 14, 2011 (JP) 2011-055454

(51) Int. Cl. H01L 29/92; H01L 21/56; H01L 23/498

(52) U.S. Cl. 257/532; 257/737; 438/124; 257/774; 257/E23.068; 257/E23.067; 257/E29.342; 257/E21.502

(57) ABSTRACT

Adhesive strength between a rewiring and a solder bump is improved in a semiconductor integrated circuit device in which a bump electrode is connected to a land section of the rewiring. The land section 20A of the rewiring 20 is formed by a five-layer metal film (a barrier metal film 13, a seed film 14, a Cu film 15, a first Ni film 16, and a second Ni film 17) constituting the rewiring 20, the uppermost-layer second Ni film 17 has a larger area than that of the other metal films (the barrier metal film 13, the seed film 14, the Cu film 15, and the first Ni film 16). A solder bump 21 is connected to the surface of the second Ni film 17. At the end portion of the solder bump 21, a polyimide resin film 22 is formed directly under the second Ni film 17.

### CROSS-REFERENCE TO RELATED APPLICATION

The disclosure of Japanese Patent Application No. 2011-55454 filed on Mar. 14, 2011 including the specification, drawings and abstract is incorporated herein by reference in its entirety.

### BACKGROUND

The present invention relates to a semiconductor integrated circuit device and a method of manufacturing the same, and particularly relates to a semiconductor integrated circuit device, in which a bump electrode as an external connection terminal or a bonding wiring is connected to a first end of a rewiring that is formed over the device surface of a semiconductor chip, and a technology that is effective when applied to an electronic system, such as a mobile electronic device, having the semiconductor integrated circuit device mounted on.

For a semiconductor integrated circuit device, a multilayer wiring is formed by metal films including copper (Cu) or aluminum (Al) alloy as a main component at an upper portion of a semiconductor substrate formed with semiconductor elements, such as, complementary metal insulator semiconductor (CMIS) transistors, and a final passivation film (surface protection film) is formed at an upper portion of the multilayer wiring.

As disclosed in Japanese Patent Laid-Open No. 2003-234348 (Patent Document 1) and Japanese Patent Laid-Open No. 2005-026301 (Patent Document 2), technology is known in which a rewiring containing Cu as a main component is formed over a final passivation film, and an electrode pad formed on an uppermost-layer wiring under the final passivation film and the rewiring are electrically connected.

### SUMMARY

Patent Document 2 discloses a semiconductor device in which a solder bump as an external connection terminal is connected to the surface of a land section, which is a first end of a rewiring. For this semiconductor device, after a rewiring is formed, an underlayer including a conductive material is formed at a lower portion of the rewiring to have a smaller area than that of the land section of the rewiring by over-etching of the conductive material.

In a forming method by over-etching of a conductive material, if an underlayer is thickened to reduce the stress applied to a solder bump, the amount of over-etching of the underlayer also becomes large, which makes it difficult to control the wiring dimension and control the wiring resistance of the underlayer, resulting in a drop in the properties of a semiconductor device. Particularly, if the wiring length of the rewiring becomes large by miniaturization, high integration, or multiple pins, drop in the properties of the semiconductor device becomes a problem.

Further, for a semiconductor integrated circuit device having a rewiring, a structure is employed where a bump electrode (solder bump) as an external connection terminal is connected to a first end (land section) of a rewiring formed over a device surface of a semiconductor chip, and the semiconductor chip is mounted on a wiring substrate or the like via this bump electrode.

The inventors mounted a semiconductor integrated circuit device with such a structure on a mobile electronic device, such as a mobile phone and a laptop, and made a vibration test and a drop shock test. As a result, the inventors discovered a phenomenon that a portion of a bump electrode connecting a semiconductor chip and a wiring substrate lost connection.

The inventors sought a cause of the disconnection, and found that the disconnection was mainly caused by that the end portion of a bump electrode peeled off from the surface of a rewiring due to vibration or drop shock and this peeling-off developed toward the center of the bump electrode.

By filling under-fill resin into the gap between the semiconductor chip and the wiring substrate, the inventors devised a solution to reinforce the adhesive force between the semiconductor chip and the wiring substrate. As a result, disconnection of a bump electrode during the vibration test and drop shock test was successfully reduced.

The above solution by filling under-fill resin into the gap between a semiconductor chip and a wiring substrate requires a manufacturing line dedicated for applying under-fill resin, which causes a problem of significant increase in the cost of a semiconductor integrated circuit device. Further, in filling under-fill resin into the gap between a bump electrode and a wiring substrate, there is also a problem of making it difficult to remove a semiconductor chip from a wiring substrate when a defect of the semiconductor chip has occurred after its mounting.

The present invention has been made in view of the above circumstances and provides a technology that improves the properties of a semiconductor integrated circuit device having a rewiring structure.

The present invention further provides a technology that improves the adhesive strength between a rewiring and an external connection terminal, for a semiconductor integrated circuit device having a structure where an external connection terminal is connected to a first end (land section) of a rewiring formed over the device surface of a semiconductor chip.

The present invention still further provides a technology that reduces the wiring resistance of a rewiring without reducing the adhesive strength between the rewiring and an external connection terminal.

The other purposes and the new feature of the present invention will become clear from the description of the present specification and the accompanying drawings.

The following explains briefly the outline of a typical invention among the inventions disclosed in the present application.

(1) A semiconductor integrated circuit device that is an embodiment of the present invention includes (a) a semiconductor substrate having a device surface; (b) a plurality of semiconductor elements formed on the device surface and a multi-layer wiring that connects between the semiconductor elements; (c) a protection film that covers, the device surface and an upper portion of an uppermost layer wiring of the multi-layer wiring; (d) a first electrode pad that is formed by a portion of the uppermost layer wiring and is exposed from a pad opening formed in the protection film; (e) a rewiring formed at the upper portion of the protection film and having the first end electrically connected to the first electrode pad through the pad opening and the second end forming a land section formation region; and (f) a first insulation film that is formed to cover the rewiring and has a first opening at the upper portion of the land section formation region, the rewiring includes a first metal film that includes a metal film including copper as a main component, and a second metal film formed at the upper portion of the first metal film, the land section formation region is formed such that an area of the second metal film is larger than that of the first metal film, and the first insulation film is formed directly under the second metal film at an end portion of a land, section to which a bump electrode is connected in the land section formation region. (2) The rewiring has a portion where the second metal film is not formed over the first metal film extending from the first electrode pad to the land section formation region. (3) The second metal film has a film thickness larger than that of the first metal film with the second metal film not formed at the upper portion thereof. (4) A rewiring not connected to the bump electrode is formed by the first metal film with the second metal film not formed at the upper portion. (5) A dummy wiring is formed by the first metal film with the second metal film not formed at the upper portion. (6) At least one of a resistance element, a capacitor, and a capacitance element is formed by the first metal film with the second metal film not formed at the upper portion.

The following explains briefly the effect acquired by the typical invention among the inventions disclosed in the present application.

The properties of a semiconductor integrated circuit device having a rewiring are improved.

For a semiconductor integrated circuit device having a structure where an external connection terminal is connected to a first end (land section) of a rewiring, the adhesive strength between the rewiring and the external connection terminal is improved.

For a semiconductor integrated circuit device having a structure where an external connection terminal is connected to a first end (land section) of a rewiring, the wiring resistance of the rewiring can be reduced without reduction in the adhesive strength between the rewiring and the external connection terminal.

### BRIEF DESCRIPTION OF THE DRAWINGS

FIG. 1 is a circuit block diagram of a semiconductor integrated circuit device in accordance with Embodiment 1 of the present invention.

FIG. 2 is an overall plan view of a semiconductor chip formed with a semiconductor integrated circuit device in accordance with Embodiment 1 of the present invention.

FIG. 3 is a plan enlarged view showing a part of FIG. 2.

FIG. 4 is a cross-sectional view taken along line A-A′ in FIG. 3.

FIG. 5 is a cross-sectional view taken along line B-B′ in FIG. 3.

FIGS. 6A and 6B are diagrams showing a dimension of each portion of a land section of a rewiring.

FIG. 7 is a cross-sectional view showing a method of manufacturing a semiconductor integrated circuit device in accordance with Embodiment 1 of the present invention.

FIG. 8 is a cross-sectional view showing the method of manufacturing a semiconductor integrated circuit device, following FIG. 7.

FIG. 9 is a cross-sectional view showing the method of manufacturing a semiconductor integrated circuit device, following FIG. 8.

FIG. 10 is a cross-sectional view showing the method of manufacturing a semiconductor integrated circuit device, following FIG. 9.

FIG. 11 is a cross-sectional view showing the method of manufacturing a semiconductor integrated circuit device, following FIG. 10.

FIG. 12 is a cross-sectional view showing the method of manufacturing a semiconductor integrated circuit device, following FIG. 11.

FIG. 13 is a cross-sectional view showing the method of manufacturing a semiconductor integrated circuit device, following FIG. 12.

FIG. 14 is a cross-sectional view showing the method of manufacturing a semiconductor integrated circuit device, following FIG. 13.

FIG. 15 is a cross-sectional view showing the method of manufacturing a semiconductor integrated circuit device, following FIG. 14.

FIG. 16 is a cross-sectional view showing the method of manufacturing a semiconductor integrated circuit device, following FIG. 15.

FIG. 17 is a cross-sectional view showing the method of manufacturing a semiconductor integrated circuit device, following FIG. 16.

FIG. 18 is a cross-sectional view showing the method of manufacturing a semiconductor integrated circuit device, following FIG. 17.

FIG. 19 is a cross-sectional view showing the method of manufacturing a semiconductor integrated circuit device, following FIG. 18.

FIG. 20 is a diagram showing a BGA semiconductor device having a semiconductor chip mounted via solder bumps on the top surface of a wiring substrate.

FIG. 21 is a diagram showing a mobile electronic device (electronic system) mounting a semiconductor integrated circuit device in accordance with Embodiment 1 of the present invention.

FIG. 22A is a cross-sectional view showing a semiconductor integrated circuit device in accordance with an other embodiment of the present invention.

FIG. 22B is a plan view showing the semiconductor integrated circuit device in accordance with an other embodiment of the present invention.

FIG. 23A is a cross-sectional view showing a semiconductor integrated circuit device in accordance with an other embodiment of the present invention.

FIG. 23B is a plan view showing the semiconductor integrated circuit device in accordance with an other embodiment of the present invention.

FIG. 24A is a cross-sectional view showing a semiconductor integrated circuit device in accordance with an other embodiment of the present invention.

FIG. 24B is a plan view showing the semiconductor integrated circuit device in accordance with an other embodiment of the present invention.

FIG. 25A is a cross-sectional view showing a semiconductor integrated circuit device in accordance with an other embodiment of the present invention.

FIG. 25B is a plan view showing the semiconductor integrated circuit device in accordance with an other embodiment of the present invention.

FIG. 26A is a cross-sectional view showing a semiconductor integrated circuit device in accordance with an other embodiment of the present invention.

FIG. 26B is a plan view showing the semiconductor integrated circuit device in accordance with an other embodiment of the present invention.

FIG. 27A is a cross-sectional view showing a semiconductor integrated circuit device in accordance with an other embodiment of the present invention.

FIG. 27B is a plan view showing the semiconductor integrated circuit device in accordance with an other embodiment of the present invention.

FIG. 28 is a partial enlarged plan view showing a semiconductor integrated circuit device in accordance with Embodiment 2 of the present invention.

FIG. 29 is a cross-sectional view taken along line A-A′ in FIG. 28.

FIG. 30 is a cross-sectional view taken along line B-B′ in FIG. 28.

FIG. 31 is a cross-sectional view showing a semiconductor integrated circuit device in accordance with Embodiment 3 of the present invention.

FIG. 32 is a cross-sectional view showing a semiconductor integrated circuit device in accordance with Embodiment 4 of the present invention.

FIG. 33 is an overall plan view of a semiconductor chip formed with a semiconductor integrated circuit device in accordance with Embodiment 5 of the present invention.

FIG. 34 is a cross-sectional view taken along line C-C′ in FIG. 33.

FIG. 35 is a cross-sectional view showing a semiconductor integrated circuit device in accordance with Embodiment 6 of the present invention.

FIG. 36 is a partial enlarged plan view showing a semiconductor integrated circuit device in accordance with Embodiment 7 of the present invention.

FIG. 37 is a cross-sectional view taken along line A-A′ in FIG. 36.

FIG. 38 is a cross-sectional view taken along line B-B′ in FIG. 36.

FIG. 39 is a partial enlarged plan view showing another example of a semiconductor integrated circuit device in accordance with Embodiment 7 of the present invention.

FIG. 40 is a cross-sectional view taken along line A-A′ in FIG. 39.

FIG. 41 is a cross-sectional view showing a method of manufacturing a semiconductor integrated circuit device in accordance with Embodiment 7 of the present invention.

FIG. 42 is a cross-sectional view showing the method of manufacturing a semiconductor integrated circuit device, following FIG. 41.

FIG. 43 is a cross-sectional view showing the method of manufacturing a semiconductor integrated circuit device, following FIG. 42.

FIG. 44 is a cross-sectional view showing the method of manufacturing a semiconductor integrated circuit device, following FIG. 43.

FIG. 45 is a cross-sectional view showing the method of manufacturing a semiconductor integrated circuit device, following FIG. 44.

FIG. 46 is a cross-sectional view showing the method of manufacturing a semiconductor integrated circuit device, following FIG. 45.

FIG. 47 is a cross-sectional view of a package in which a semiconductor chip in Embodiment 7 is resin-sealed.

FIG. 48 is a cross-sectional view showing another semiconductor integrated circuit device in accordance with Embodiment 7 of the present invention.

### DETAILED DESCRIPTION

Embodiments of the present invention will be described below in detail, based on the drawings. In all the drawings for explaining embodiments, the same symbol is attached to members having the same function, and the repeated explanation thereof is omitted. In the embodiments, explanation of the same or a similar part is not repeated unless necessary. In the drawings for illustrating the embodiments, in order to make a drawing intelligible, hatching may be attached even if it is a plan view, and hatching may be omitted even if it is a cross-sectional view.

### Embodiment 1

A semiconductor integrated circuit device (semiconductor device) in the present embodiment includes an integrated circuit that has a plurality of semiconductor elements formed on the device surface of a semiconductor chip and wiring of plural layers (multi-layer wiring) for connection between the semiconductor elements. A semiconductor integrated circuit device is mounted on a mobile electronic device, such as, a mobile phone or a laptop. A semiconductor integrated circuit device to be mounted on a mobile electronic device may be a CPU, a microprocessor, a controller, an analog circuit, a logic circuit such as a circuit for high-frequency communication, a storage circuit such as a memory, or a logic circuit mounting a storage circuit. Further, this semiconductor integrated circuit device may be one applied to an IC for a hard disk drive (HDD).

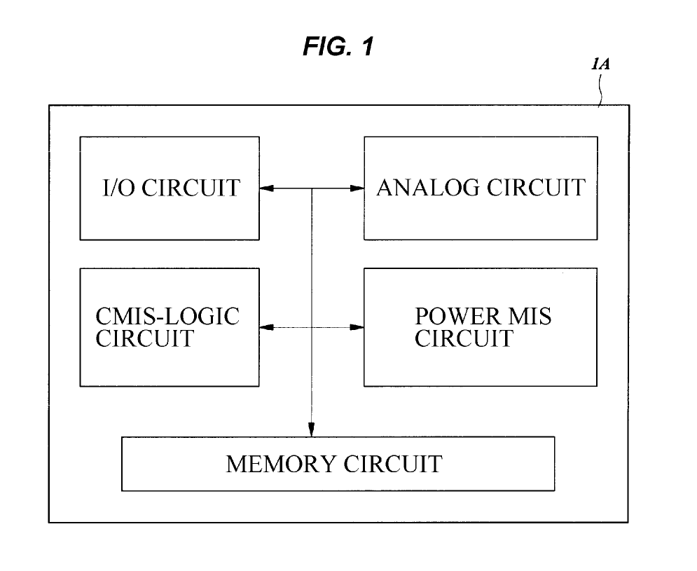

FIG. 1 is a circuit block diagram of a semiconductor integrated circuit device. As shown in FIG. 1, a semiconductor integrated circuit device includes an input/output (I/O) circuit, an analog circuit, a CMIS-logic circuit, a power MIS circuit, and a memory circuit, which are formed on the device surface of a semiconductor chip 1A.

Among the circuits of the semiconductor integrated circuit device, the CMIS-logic circuit includes a CMIS transistor with an operation voltage of 1 to 3 V, and the I/O circuit and the memory circuit includes a CMIS transistor with an operation voltage of 1 to 3 V or 5 to 8 V. The CMIS transistor with the operation voltage of 1 to 3 V includes a first n-channel metal insulator semiconductor field effect transistor (MISFET) having a first gate insulation film, and a first p-channel MISFET having a first insulation film. The CMIS transistor with the operation voltage of 5 to 8 V includes a second n-channel MISFET having a second gate insulation film, and a second p-channel MISFET having a second gate insulation film. The film thickness of the second gate insulation film is made larger than that of the first gate insulation film. An MISFET will be referred to as an MIS transistor in the description below.

The analog circuit includes the CMIS transistor (or bipolar transistor) with an operation voltage 5 to 8 V, a resistance element, and a capacitance element. A power MIS circuit includes the CMIS transistor with an operation voltage of 5 to 8 V and a high-voltage MIS transistor (high-voltage resistant element) with an operation voltage of 20 to 100 V.

The high-voltage MIS transistor is configured with, for example, a third n-channel MISFET having a third gate insulation film, a third p-channel MISFET having a third gate insulation film, or the both. If a voltage of 20 to 100 V is applied between the gate electrode and a drain region or between the gate electrode and a source region, the film thickness of the third gate insulation film is made larger than that of the second gate insulation film.

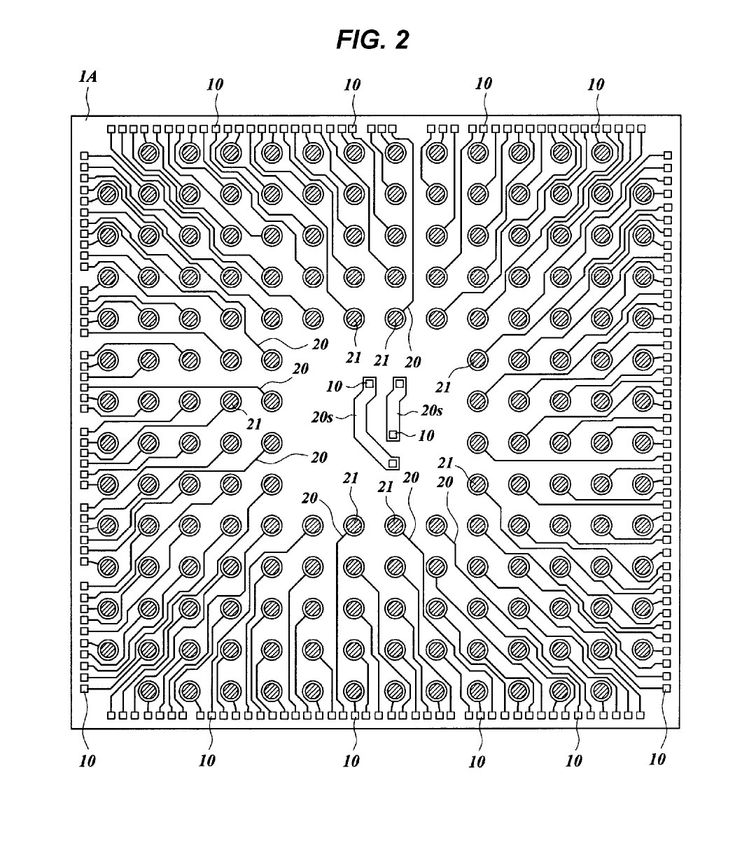

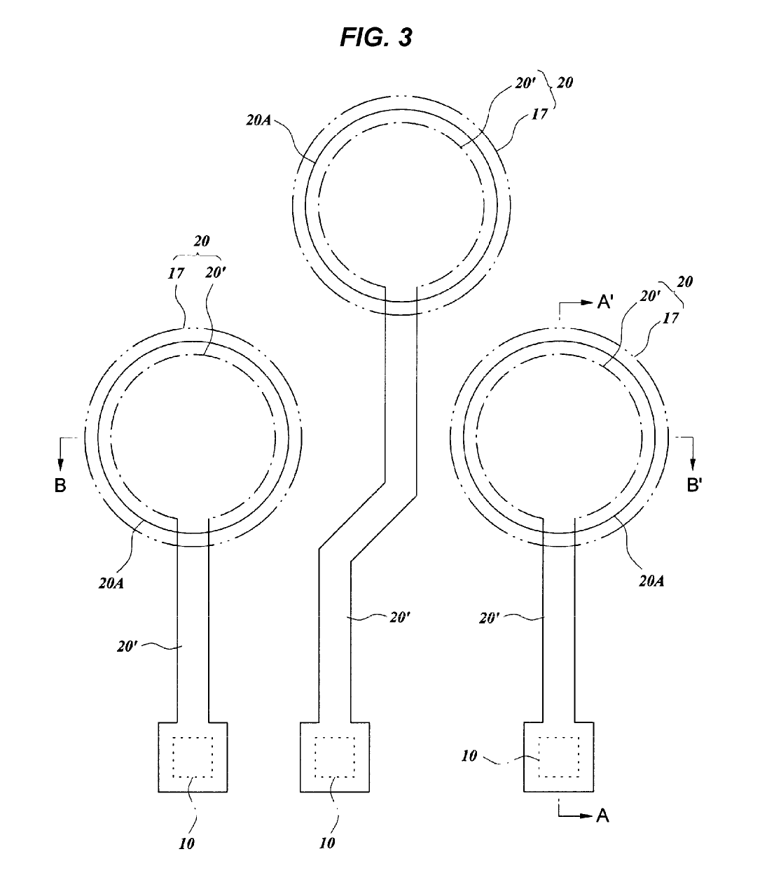

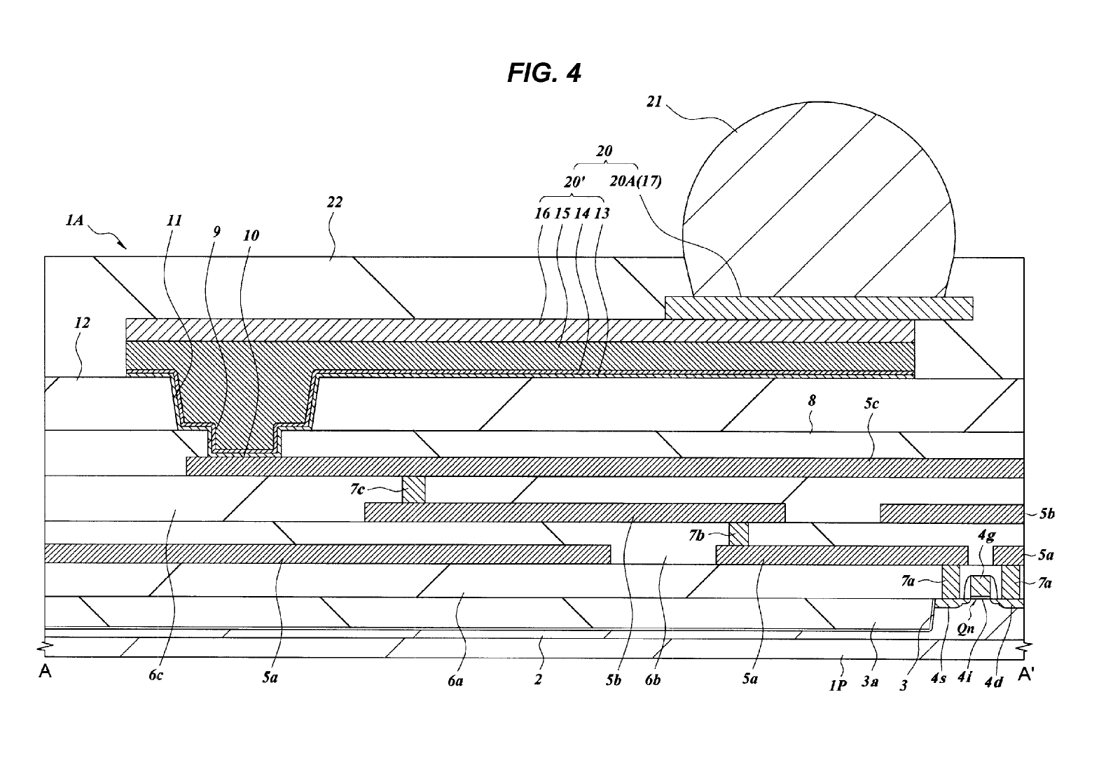

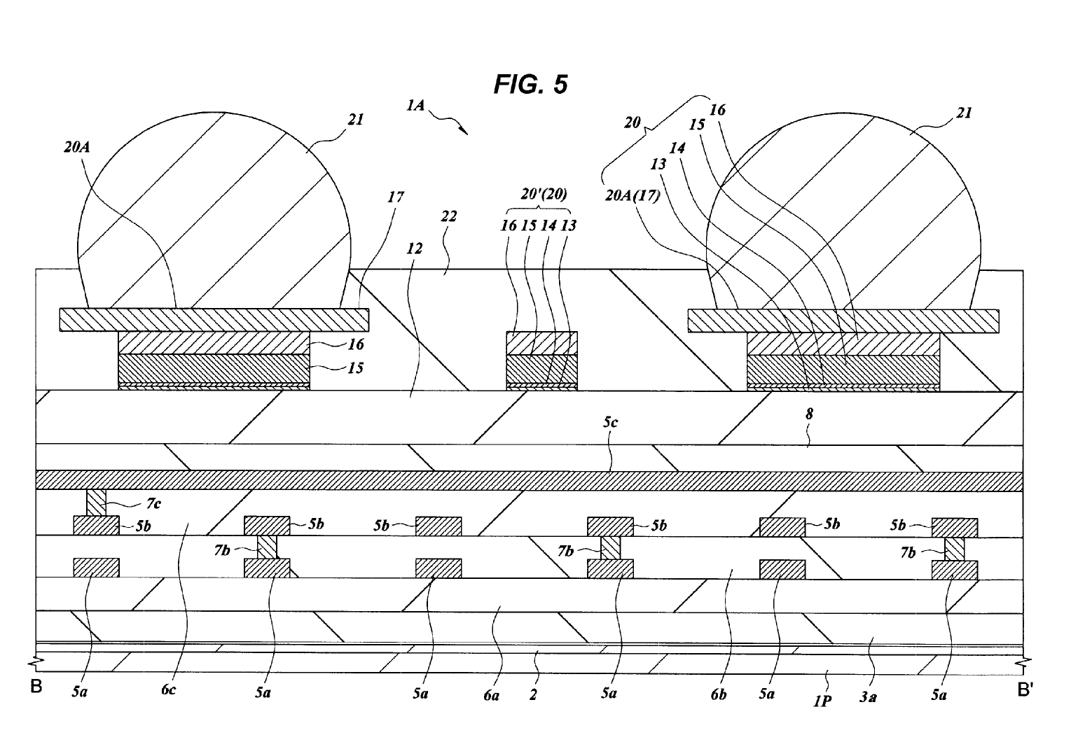

FIG. 2 is an overall plan view of the semiconductor chip 1A formed with the above-mentioned circuits. FIG. 3 is an enlarged plan view showing a part of FIG. 2. FIG. 4 is a cross-sectional view taken along line A-A′ in FIG. 3. FIG. 5 is a cross-sectional view taken along line B-B′ in FIG. 3. FIGS. 2 and 3 show a state that a polyimide resin film of the uppermost layer is removed.

As shown in FIGS. 4 and 5, on a semiconductor substrate 1P made from p-type single crystal silicon, a p-type well 2 and an element isolation groove 3 are formed. Inside the element isolation groove 3, an element isolation insulation film 3a which is made from silicon oxide film is embedded.

Over the p-type well 2, an n-channel MIS transistor (Qn) is formed. The n-channel MIS transistor (Qn) includes a source region 4s and a drain region 4d formed in the p-type well 2 that is an active region defined by the element isolation groove 3, and a gate electrode 4g formed over the p-type well 2 via a gate oxide film 4i. For the real semiconductor substrate 1P, further formed are various semiconductor elements, such as a n-type well, a p-channel MIS transistor, a resistance element, and a capacitance element, but FIGS. 4 and 5 show only the n-channel MIS transistor (Qn) as a semiconductor element that constitutes the semiconductor integrated circuit device. The source region 4s, the drain region 4d, and the gate electrode 4g of the n-channel MIS transistor (Qn), which is a semiconductor element, are electrically connected to another semiconductor element or a power supply wiring through a later-described multi-layer wiring.

At the upper portion of the n-channel MIS transistor (Qn), wirings of metal films are formed to connect between semiconductor elements. In general, wirings connecting between semiconductor elements have a multi-layer wiring structure of approximately 3 to 10 layers. As a multi-layer wiring, FIGS. 4 and 5 show a three-layer wiring (first layer wiring 5a, second layer wiring 5b, and third layer wiring 5c) formed by a metal film, which is a conductive film containing copper (Cu) or aluminum (Al) alloy as a main component.

Further, between the n-channel MIS transistor (Qn) and the first layer wiring 5a, between the first layer wiring 5a and the second layer wiring 5b, and between the second layer wiring 5b and the third layer wiring 5c, formed are inter-layer insulation films 6a, 6b, and 6c made of a silicon oxide film, a low dielectric film (such as SiCO film, SiCON film, and SiCO film) with an dielectric constant lower than that of a silicon oxide film, or the like.

The inter-layer insulation film 6a of the first layer is formed over the semiconductor substrate 1P to cover semiconductor elements, and the first layer wiring 5a is formed over the inter-layer insulation film 6a. The first layer wiring 5a is electrically connected, through a plug 7a formed through the inter-layer insulation film 6a, with semiconductor elements, such as, the source region 4s, the drain region 4d, and the gate electrode 4g of the n-channel MIS transistor (Qn).

The second layer wiring 5b formed over the inter-layer insulation film 6b of the second layer is electrically connected to the first layer wiring 5a through a plug 7b formed in the inter-layer insulation film 6b. Further, the third layer wiring 5c formed over the inter-layer insulation film 6c of the third layer is electrically connected to the second layer wiring 5b through a plug 7c formed in the inter-layer insulation film 6c. The plugs 7a, 7b, and 7c are formed by a metal film, such as a W (tungsten) film.

The multi-layer wiring (three layer wiring) is formed by metal films and plugs. In forming the multi-layer wiring with metal films containing copper (Cu) as a main component by using a chemical mechanical polishing (CMP) method, the wirings and the plugs may be integrally formed by a dual damascene method. Further, in this case, the inter-layer insulation films 6a, 6b, and 6c may be formed by, in place of the silicon oxide film, a single-layer film or a laminated layer film of low dielectric films with a lower dielectric constant than that of a silicon oxide film, such as a silicon oxide film including carbon (SiOC film), a silicon oxide film including nitrogen and carbon (SiCON film), or a silicon oxide film including fluorine (SiOF film).

At the upper portion of the third layer wiring 5c, which is the uppermost layer wiring of the multi-layer wiring (three layer wiring), formed is as a final passivation film a surface protection film 8 that is a single layer film of a silicon oxide film or a silicon nitride film, or a two layer film with lamination of these insulation films. Further, a portion of the surface protection film 8 is formed with a pad opening 9, and the uppermost layer wiring (the third layer wiring 5c) exposed at the bottom of the pad opening 9 forms a pad (first electrode pad) 10, which is an electrode pad. Pads 10 are arrayed in a row along each side of the semiconductor chip 1A, as shown in FIG. 2. The pads 10 may be also disposed zigzag or in three rows or more along each side of the semiconductor chip 1A. The uppermost layer wiring may be formed from a high-melting metal film, with the pad 10 as the main body. The high-melting metal film can be a single film or a lamination film laminating plural films of tantalum (Ta) film, titanium (Ti) film, titanium nitride (TiN) film, tantalum nitride (TaN) film, Nickel (Ni) film, and palladium (Pd) film. Further, the lamination film can be a two-layer lamination film with a thin palladium (Pd) film formed at the upper portion of a thick nickel (Ni) film, or a three-layer lamination film obtained by forming a thick nickel (Ni) film at the upper portion of a titanium nitride. (TiN) film and forming a thin palladium (Pd) film at the upper portion of this thick nickel (Ni) film.

A polyimide resin film 12, which is an insulation film, is formed at the upper portion of the surface protection film 8. The polyimide resin film 12 above the pad opening 9 is provided with an opening 11. Further, at the upper portion of the polyimide resin film 12, a rewiring 20 is formed which is electrically connected to the pad 10 through the opening 11 of the polyimide resin film 12 and the pad opening 9 of the surface protection film 8. The polyimide resin film 12 is formed thicker than the surface protection film 8.

As shown in FIGS. 4 and 5, the rewiring 20 is formed by a metal film of a five layer film obtained by sequentially laminating, from the bottom layer, a barrier metal film 13, a seed film 14, a copper (Cu) film 15 which is a conductive film, and a two layer nickel (Ni) film (first Ni film 16 and second Ni film 17) which is a conductive film. The barrier metal film 13 is formed from a thin chrome (Cr) film with a thickness of approximately 50 to 80 nm, and the seed film 14 is formed from a thin Cu film with a thickness of approximately 200 to 300 nm. The Cu film 15, which is a conductive film, is a thick film with a thickness of approximately 4 to 7 μm. The first Ni film 16 and the second Ni film 17, which are conductive films, have a thickness of approximately 2.5 to 3.5 μm.

In the five layer metal film forming the rewiring 20, the Cu film 15, which is a conductive film, has the lowest electrical resistance and has a larger film thickness than other conductive film. Accordingly, the electrical resistance of the rewiring 20 is about equal to that of this Cu film 15. The electrical resistance of the rewiring 20 is about equal to that of the conductive material (Cu) having a lower electrical resistance compared with the lower layer wiring (first layer wiring 5a, second layer wiring 5b, and third layer wiring 5c). The thickness of the rewiring 20 is larger than that of the multi-layer wiring of the lower layer (first layer wiring 5a, second layer wiring 5b, and third layer wiring 5c). The wiring resistance of the rewiring 20 is lower than that of the multi-layer wiring of the lower layer (first layer wiring 5a, second layer wiring 5b, and third layer wiring 5c).

As shown in FIG. 3, the rewiring 20 has a structure in which at a first end of the wiring section formed by the first layer metal film (first metal film) 20′, a land section 20A is formed which has a laminated structure with the first layer metal film 20′ and the second layer metal film (second metal film), which are wider than the wiring section. Further, as shown in FIGS. 4 and 5, a ball-shaped solder bump 21 (bump electrode) forming the external connection terminal of the circuit shown in FIG. 1 is connected with the surface of the land section 20A. In FIG. 3, the rewiring 20 is shown in a state that the solder bump 21 is removed.

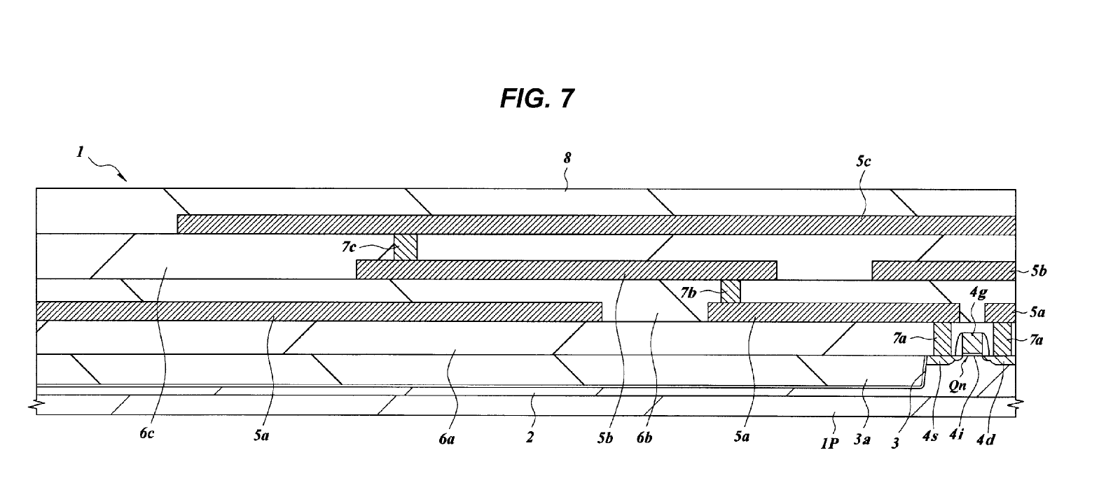

As will be explained in the description of a manufacturing method using later-described FIGS. 7 to 19, the first layer metal film (first metal film) 20′ is formed, using a photoresist pattern film 31, which is the first mask, and an opening 30, and mainly includes the copper (Cu) film 15 and the first Ni film 16 which are conductive films. Further, the second layer metal film (second metal film) is formed, using a photoresist pattern film 33, which is the second mask with a plane pattern different from that of the first mask, and an opening 32, and mainly includes the second Ni film 17 which is a conductive film. In such a manner, because the land section 20A of the rewiring 20 is formed in a structure where the second metal film (second Ni film 17) is laminated at the upper portion of the first layer metal film 20′, it is possible to reduce the wiring resistance of the rewiring 20 and improve the properties of the semiconductor integrated circuit device (semiconductor device). A first end (land section 20A) of the rewiring 20, which is connected to the solder bump 21 is, as shown in FIG. 2, disposed in a matrix shape on the device surface of the semiconductor chip 1A. A second end of the rewiring 20 is connected to the pad 10 of the above-mentioned third layer wiring 5c, in the periphery of the device surface of the semiconductor chip 1A.

Further, as will be described later, by forming the thickness of the first layer metal film 20′ to be larger than the thickness of the second layer metal film (second Ni film 17), the wiring resistance of the rewiring 20 can be reduced without reducing the adhesive strength between the rewiring 20 and the solder bump 21. The portion (the wiring section formed by the first layer metal film 20′) of the rewiring 20 other than the land section formation region is formed with a structure where the second layer metal film (second Ni film 17) is not formed at the upper portion of the first layer metal film 20′. In the rewiring 20 extending from the pad (first electrode pad) 10 to the land section 20A, in the region other than the land section 20A, the second layer metal film (second Ni film 17) is not formed at the upper portion of the first layer metal film 20′.

Further, the first mask and the second mask which has a plane pattern different from that of the first mask are used to form the rewiring 20. It is possible to improve the controllability of the dimensions of the rewiring 20, the controllability of the wiring resistance, and the properties of the semiconductor integrated circuit device. As shown in FIG. 2, even if miniaturization, high-integration, and multiple-pins are accelerated and the wiring length of the rewiring 20 is made larger, the properties of the semiconductor integrated circuit device can be improved.

Further, as the second layer metal film (second Ni film 17) is required to be formed only in the land section formation region, the degree of freedom of designing a wiring section is improved, and miniaturization, high integration, and multiple pins can be accelerated, which improves the properties of a semiconductor integrated circuit device. Still further, as described later, the film thickness of the polyimide resin film 22, which is an insulation film at the upper portion of the wiring section, is larger at a portion as an insulation film at the upper portion of the wiring section than at a portion as an insulation film at the upper portion of the second layer metal film. Thus, it is possible to improve the reliability of the semiconductor integrated circuit device and the properties of the semiconductor device. Further, when the efficiency in dicing a wafer, damage caused through the dicing, and the like are taken into account, even if the thickness of the polyimide resin film 22 is made small, the film thickness of the polyimide resin film 22, which is an insulation film at the upper portion of the wiring section, is large, and the properties of the semiconductor integrated circuit device can be accordingly improved.

Parts of the plural solder bumps 21 formed on the device surface of the semiconductor chip 1A shown in FIG. 2 are external connection terminals for signal, which are electrically connected to a rewiring 20 for signal input/output. Further, the rest of the plural solder bumps 21 are external connection terminals for power supply (Vcc and GND), which are electrically connected to a rewiring 20 for power supply (Vcc and GND). The rewiring 20 for signal input/output is electrically connected to an MIS transistor through wirings (first layer wiring 5a, second layer wiring 5b, and third layer wiring 5c), which are wirings for signal input/output. The rewiring 20 for power supply is electrically connected to an MIS transistor through wirings (first layer wiring 5a, second layer wiring 5b, and third layer wiring 5c), which are wirings for power supply.

Further, as shown in FIG. 2, using a structure similar to that of the portion (wiring section) other than the land section formation region, a rewiring 20s that is not connected to the solder bump 21 may be formed. That is, the rewiring 20s is formed with a structure where the second layer metal film is not formed at the upper portion of the first metal film 20′. The rewiring 20s is used as a signal wiring or a power supply wiring, and is electrically connected to an MIS transistor through wirings (first layer wiring 5 second layer wiring 5b, and third layer wiring 5c). In such a manner, by forming the rewiring 20s by the use of the first layer metal film 20′, effects similar to those of the wiring section of the above-mentioned rewiring 20 can be attained.

As shown in FIGS. 4 and 5, the upper portion of rewiring 20 is covered by the second layer polyimide resin film 22, which is an insulation film, except the upper portion of the land section 20A connected with the solder bump 21. The device surface of the semiconductor chip 1A is covered by the polyimide resin film 22, which is an insulation film, except the upper portion of land section 20A connected with the solder bump 21.

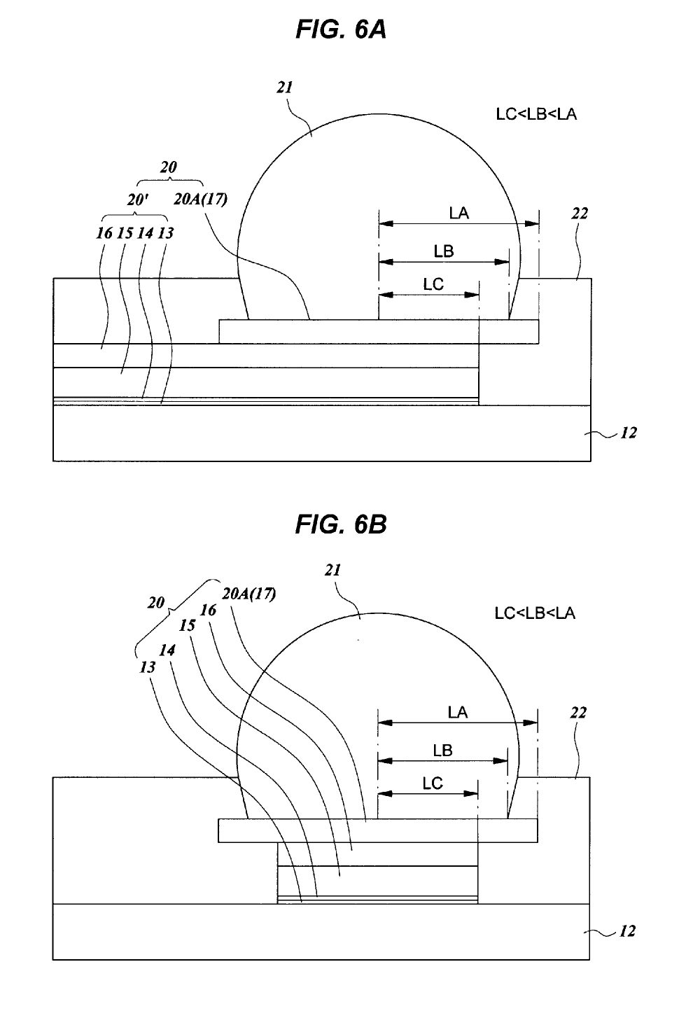

The dimensions of the portions of the land section 20A of the rewiring 20, which corresponds to the land section formation region in FIG. 4, is shown in FIG. 6A. Further, the dimensions of the portions of the land section 20A of the rewiring 20, which corresponds to the land section formation region in FIG. 5, is shown in FIG. 6B.

Symbol LA in FIGS. 6A and 6B represents the distance (hereinafter, the distance along a plane parallel to the device surface of the semiconductor chip 1A) from the center of the land section 20A to the end portion of the second Ni film 17, which is a conductive film. Further, symbol LB represents the distance from the center of the land section 20A to the end portion (the boundary surface between the lower end portion of the solder bump 21 and the second layer polyimide resin film 22, which is an insulation film) of the solder bump 21. Further, symbol LC represents the distance from the center of the land section 20A to the end portion of the first layer metal film 20′ (the distance to each of the ends of the first Ni film 16), which is a conductive film, the CU film 15, which is a conductive film, the seed film 14, and the barrier metal film 13. In accordance with the embodiment, at the land section 20A of the rewiring 20, the dimensions of the above-mentioned portions have a relationship expressed by LC<LB<LA.

The land section 20A of the rewiring 20 is arranged in the following manner. Of the five-layer metal film (barrier metal film 13, seed film 14, Cu film 15, first Ni film 16, and second Ni film 17) forming the rewiring 20, the area of the second Ni film 17 (second layer metal film), which is the uppermost-layer metal film, is larger than the areas of the other metal films (barrier metal film 13, seed film 14, Cu film 15, and first Ni film 16), and the solder bump 21 is connected to the surface of the second Ni film 17. At the end portion of the solder bump 21, the rewiring 20 is formed only by a single-layer metal film (second layer metal film; second Ni film 17), and the polyimide resin film 22, which includes an insulation film of a material softer than a metal film, is formed directly under the second Ni film 17.

In such a manner, when a stress is applied from outside the semiconductor chip 1A to the end portion of the solder bump 21, which forms the external connection terminal, this stress is reduced and absorbed by the polyimide resin film 22, which is an insulation film formed below the end portion of the solder bump 21. Thus, the problem that the end portion of the solder bump 21 peels off from the surface of the land section 20A is controlled. Accordingly, the adhesive strength between the solder bump 21 and the land section 20A is improved.

Further, the film thickness of the first layer metal film 20′ (barrier metal film 13, seed film 14, Cu film 15, and first Ni film 16) is formed larger than the film thickness of the second layer metal film (second Ni film 17) so that the wiring resistance of the rewiring 20 can be reduced without reducing the adhesive strength between the rewiring 20 and the solder bump 21. Still further, the polyimide resin film 22, as an insulation film at the upper portion of the wiring section, has a film thickness larger than that of the polyimide resin film 22, as an insulation film at the upper portion of the second layer metal film (second Ni film 17). Accordingly, it is possible to improve the reliability of the semiconductor integrated circuit device and the properties of the semiconductor integrated circuit device.

A method of manufacturing a semiconductor integrated circuit device (semiconductor device) in accordance with the embodiment will be described below. FIG. 7 shows a state that, according to an ordinary manufacturing method, semiconductor elements and a three-layer wiring (first layer wiring 5a, second layer wiring 5b, and third layer wiring 5c) connecting the semiconductor elements are formed on the device surface of a semiconductor wafer 1 which the semiconductor elements and the three-layer wiring form, and subsequently, a surface protection film 8, which is the final passivation film, is deposited at the upper portion of the third layer wiring 5c.

FIG. 7 shows a process for coating, with the surface protection film 8, the upper portion of the device surface of the semiconductor wafer 1 formed with a plurality of semiconductor elements (such as n-channel MIS transistors Qn) and a multi-layer wiring (first layer wiring 5a, second layer wiring 5b, and third layer wiring 5c) connecting the semiconductor elements. The surface protection film 8 is formed by a silicon oxide film, a silicon nitride film, or a two-layer film of these, and is formed at the upper portion of the uppermost layer wiring (third layer wiring 5c) of the multi-layer wiring by a CVD (Chemical Vapor Reposition) method. FIG. 7 shows only an n-channel MIS transistor (Qn) as a semiconductor element constituting the semiconductor integrated circuit device.

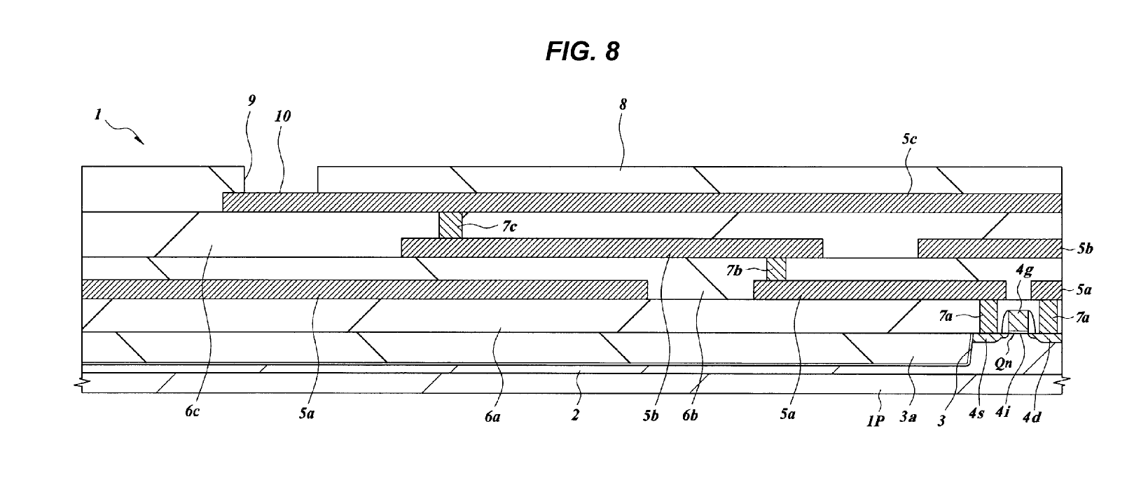

Then, as shown in FIG. 8, by dry etching using a photoresist film (not shown) as a mask, the surface protection film 8 is etched to form a pad opening 9 at the etched portion, and a portion of the third layer wiring 5c is exposed. Thus, a pad 10 which is an electrode pad is formed.

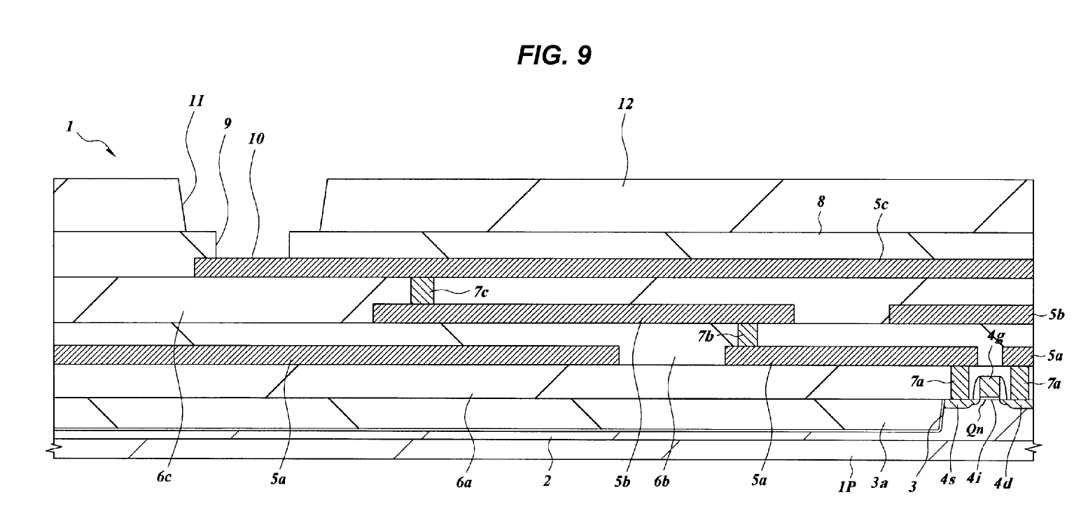

Then, as shown in FIG. 9 after the polyimide resin film 12, which is an insulation film, is deposited at the upper portion of the surface protection film 8, dry etching is performed using the photoresist film as a mask to form an opening 11 in the polyimide resin film 12 at the upper portion of the pad 10, so that the pad 10 is exposed. The polyimide resin film 12 at the upper portion of the pad 10 is etched to expose the pad 10.

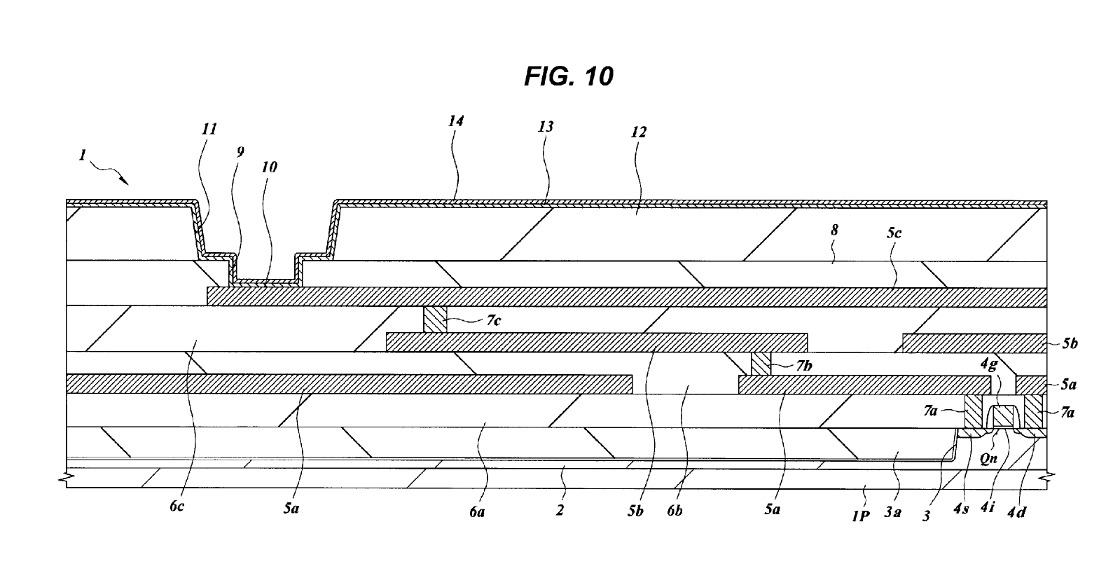

Then, as shown in FIG. 10, the barrier metal film 13 for prevention of diffusion of Cu is deposited on the entire surface of the semiconductor wafer 1, and then the seed film (metal seed film) 14 for Cu electrolytic plating is deposited at the upper portion of the barrier metal film 13. The barrier metal film 13 and the seed film 14 are formed over the device surface including the top surface of the pad 10. The barrier metal film 13 is formed from a Cr film with a film thickness of approximately 75 nm which is deposited by sputtering, and the seed film 14 is formed from a Cu film with a film thickness of approximately 250 nm deposited by sputtering. Instead of the Cr film, it is also possible to use a Ti (titanium) film, a TiN (titanium nitride) film, a WN (tungsten nitride) film, or the like as the barrier metal film.

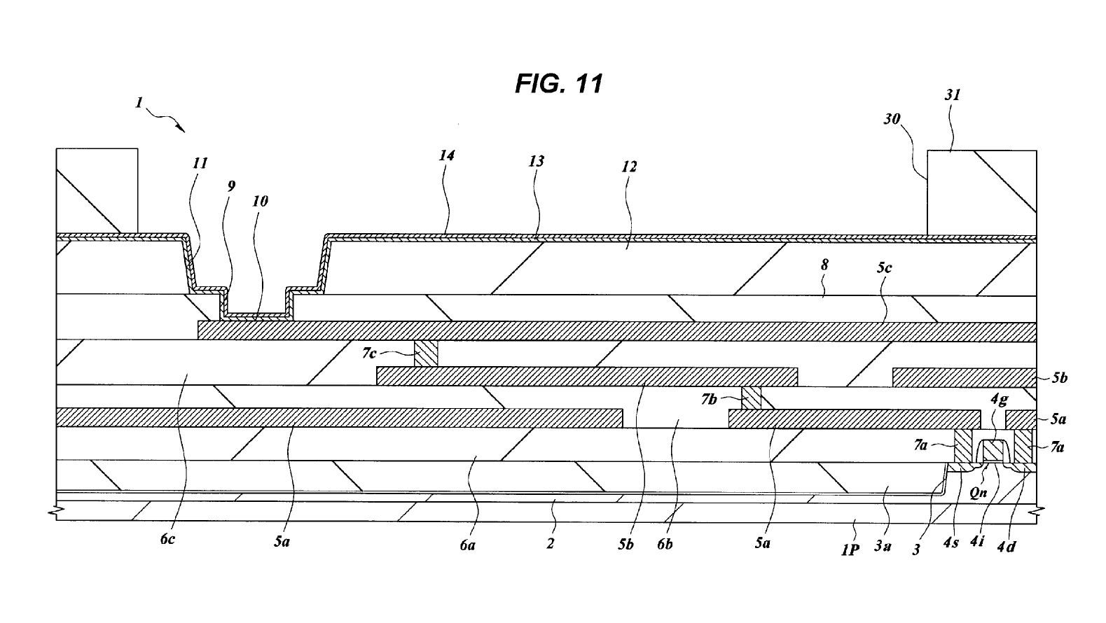

Then, as shown in FIG. 11, a photoresist film with a thickness of approximately 8 to 12 μm is deposited on the entire surface of the semiconductor wafer 1, and then this photoresist film is exposed and developed so that a photoresist film pattern (the first mask) 31 having an opening 30 at the portion is formed.

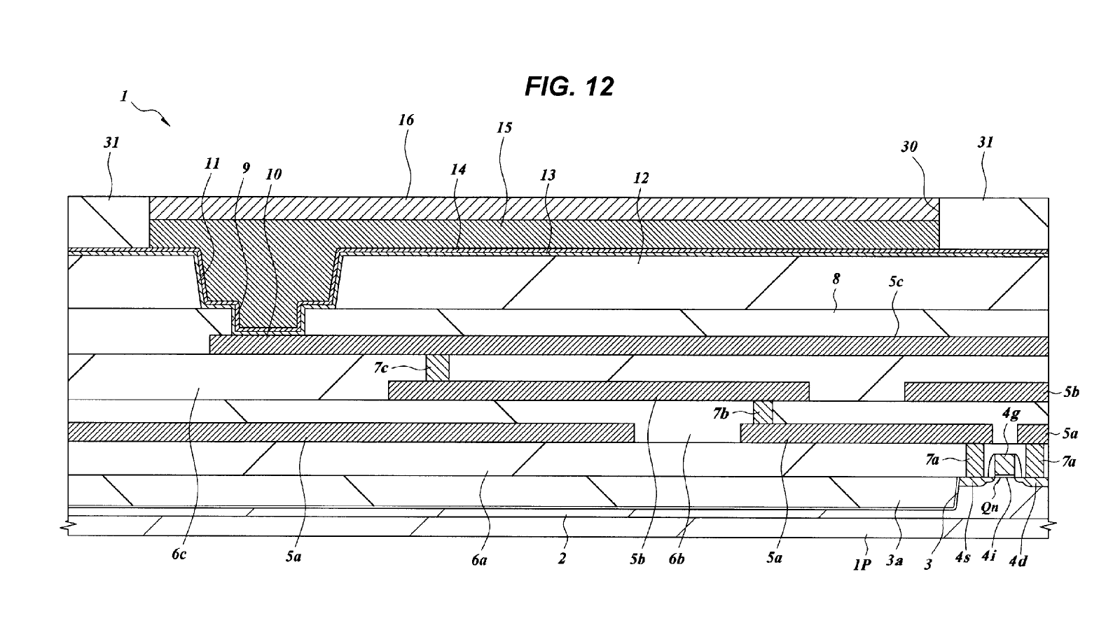

Then, as shown in FIG. 12, the Cu film 15 with a film thickness of approximately 6 to 8 μm is deposited on the surface of the seed film 14 exposed at the bottom of the opening 30 of the photoresist film pattern 31 by electrolytic plating, and then the first Ni film 16 with a thickness of approximately 1 to 3 μm is deposited on the surface of the Cu film 15. The first Ni film 16 deposited on the surface of the Cu film 15 has a function to control interdiffusion between the solder bump 21 to be connected in a later process with the land section 20A of the rewiring 20 and the Cu film 15.

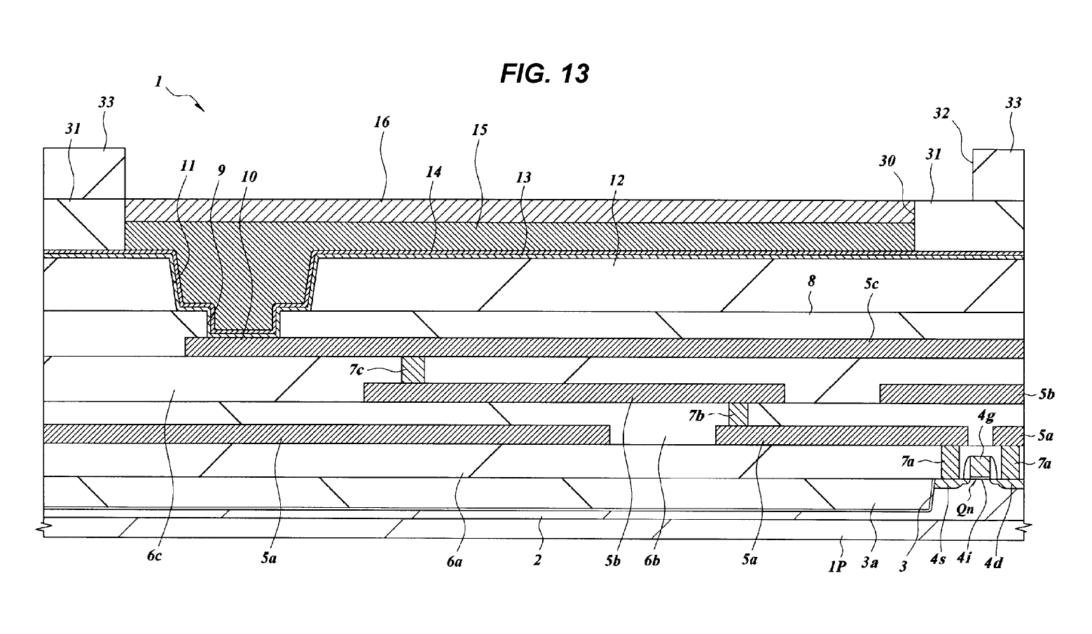

Next, as shown in FIG. 13, in a state of leaving the photoresist film pattern 31, a photoresist film with thickness of approximately 8 to 12 μm is deposited on the entire surface of the semiconductor wafer 1, and then this photoresist film is exposed and developed to form a photoresist film pattern (the second mask) 33 having an opening 32 at the portion. The opening 32 of the photoresist film pattern 33 is made larger at a portion corresponding to the land section 20A of the rewiring 20 than the opening 30 of the photoresist film pattern 31 to form a land section formation region. However, the portion corresponding to the other portion (wiring section) of the rewiring 20 is not formed with an opening.

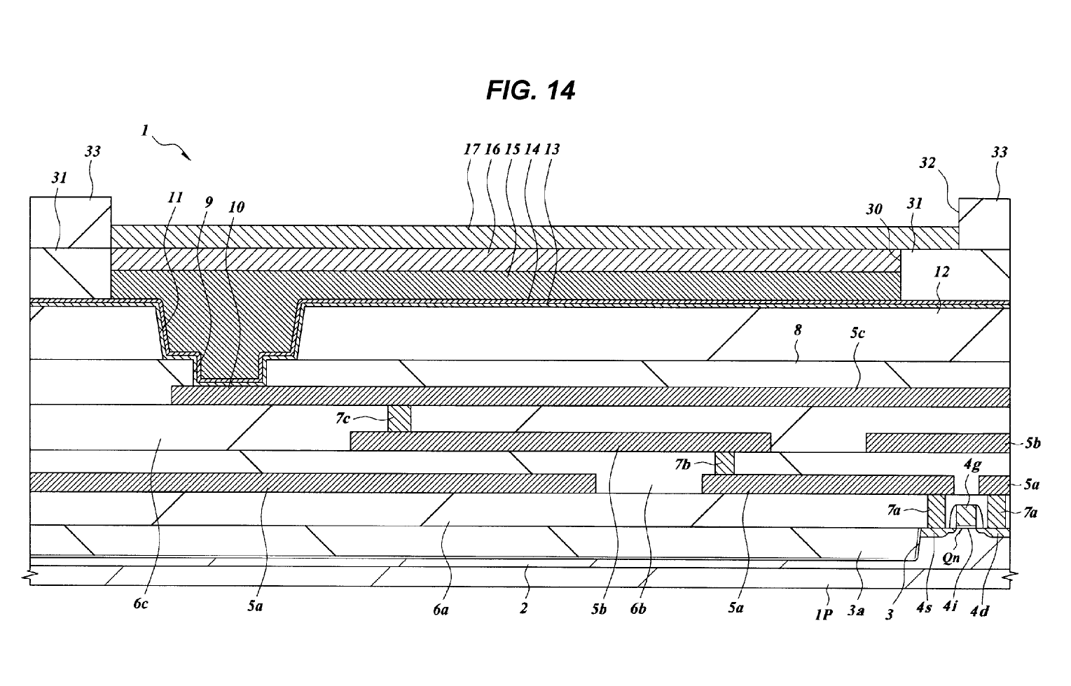

As shown in FIG. 14, the second Ni film 17 with a thickness of approximately 1 to 3 μm is deposited on the surface of the first Ni film 16, which is exposed at the bottom of the opening 32 of the photoresist film pattern 33. Further, the opening 32 of the photoresist film pattern 33 is larger, at the portion corresponding to the land section 20A of the rewiring 20, than the opening 30 of the photoresist film pattern 31. Accordingly, at the portion corresponding to the land section 20A, the second Ni film 17 is also deposited on the surface of the photoresist film pattern 31.

The five layer metal film (barrier metal film 13, seed film 14, Cu film 15, first Ni film 16, and second Ni film 17) in the region of the opening 32 (the land section formation region) becomes the land section formation region with a structure where the second layer Ni film 17 is formed at the upper portion of the first layer metal film 20′. The four layer metal film (barrier metal film 13, seed film 14, Cu film 15, and first Ni film 16) in the region of the opening 30 other than the land section formation region becomes the portion (wiring section) of the rewiring 20 other than the land section formation region, and forms the first layer metal film 20′.

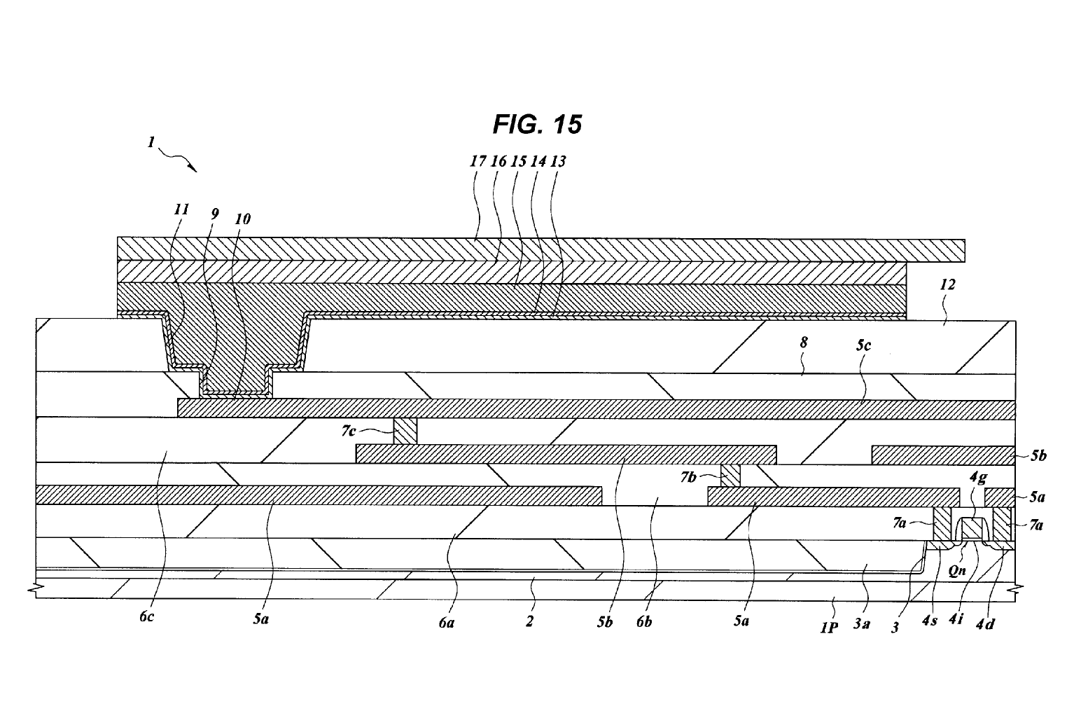

Then, as shown in FIG. 15, two layers of the photoresist film patterns 31 and 32 which have become unnecessary are removed by solvent or ashing, and subsequently the unnecessary seed film 14 and barrier metal film 13 exposed in the region where the photoresist film pattern 31 has been removed are removed by wet etching. The seed film 14 is removed by a wet etching process with hydrogen peroxide solution with a temperature of approximately 25° C. for approximately 7 to 13 seconds. The barrier metal film 13 is removed by a wet etching process with mixed solution of potassium permanganate and sodium metasilicate with a temperature of approximately 25° C. for approximately 17 to 23 minutes.

Using the photoresist film pattern 31 which is the first mask and the opening 30, the copper(Cu) film 15 and the first Ni film 16 which are conductive films are formed to form the first layer metal film (first metal film) 20′. Further, using the photoresist film pattern 33 which is the second mask with a plane pattern different from that of the first mask and the opening 32, the second Ni film 17 which is a conductive film is formed to form the second layer metal film (second metal film).

The land section formation region of the rewiring 20 is formed with a structure where the second layer metal film (second Ni film 17) is formed at the upper portion of the first layer metal film 20′, and the portion (wiring section) other than the land section formation region of the rewiring 20 is arranged with a structure where the second layer metal film (second Ni film 17) is not formed at the upper portion of the first layer metal film 20′.

The rewiring 20 has a portion, where the second layer metal film (second Ni film 17) is not formed at the upper portion of the first layer metal film 20′, in the first layer metal film 20′ extending from the pad (the first electrode pad) 10 to the land section 20, in the region other than the land section formation region. Further, by forming the rewiring 20 using the first mask and the second mask with a plane pattern different from that of the first mask, it is possible to improve the controllability of the wiring dimensions of the rewiring 20, the controllability of the wiring resistance, and the element properties of the semiconductor integrated circuit device. Further, even if miniaturization, high-integration, and multiple pins are accelerated and the wiring length of rewiring 20 is made larger; the element properties of the semiconductor integrated circuit device can be improved. Further, as described later, by making the film thickness of the first layer metal film 20′ larger than that of the second layer metal film (second Ni film 17), the wiring resistance of the rewiring 20 can be reduced without reduction in the adhesive strength between the rewiring 20 and the solder bump 21.

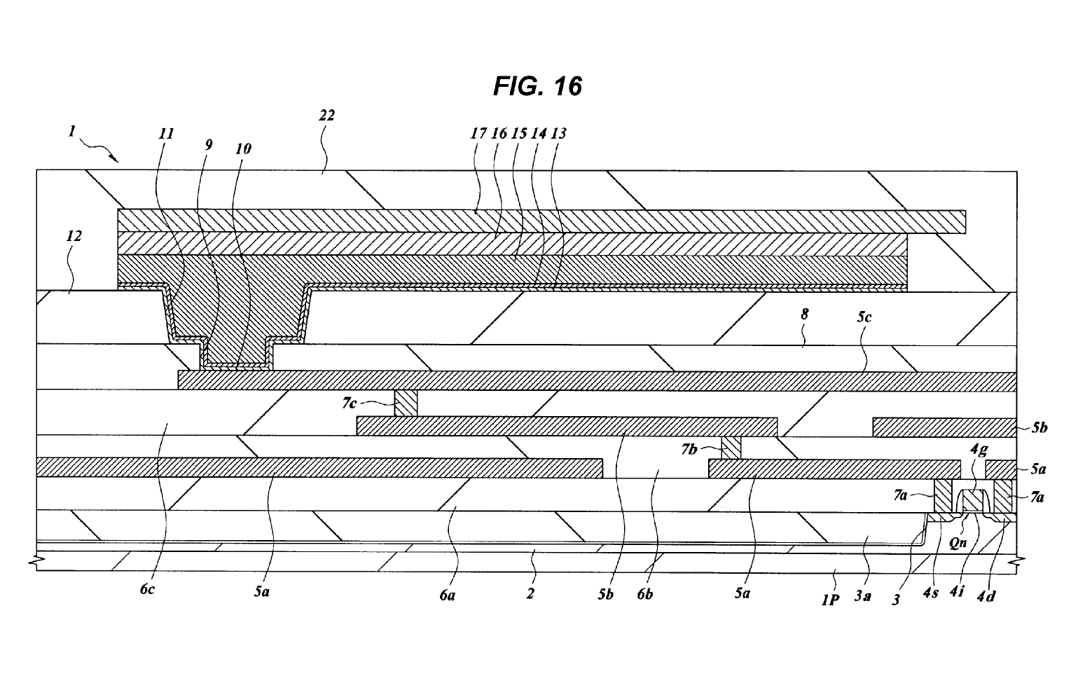

Then, as shown in FIG. 16, the second layer polyimide resin film 22 is deposited on the entire surface of the semiconductor wafer 1 to cover the side surfaces of the five layer metal film (barrier metal film 13, seed film 14, Cu film 15, first Ni film 16, and second Ni film 17) and the surface of the uppermost layer metal film (second Ni film 17) with the polyimide resin film 22, which is an insulation film. At the portion corresponding to the peripheral portion of the land section 20A of the rewiring 20, the lower surface of the second Ni film 17 is also covered by the polyimide resin film 22.

Although the film thickness of the second Ni film 17 is not limited to the above-mentioned value (approximately 1 to 3 μm), if the film thickness of the second Ni film 17 is too large, as the stress applied to the end portion of the solder bump 21 is not transmitted to the polyimide resin film 22 at a portion directly under the second Ni film 17, it becomes impossible for the polyimide resin film 22 to reduce and absorb this stress. If the film thickness of the second Ni film 17 is too small, the second Ni film 17 might be destroyed at a portion under the end portion of the solder bump 21 by the stress applied to the end portion of the solder bump 21. Accordingly, it is necessary to optimize the film thickness of the second Ni film 17, taking into account these points.

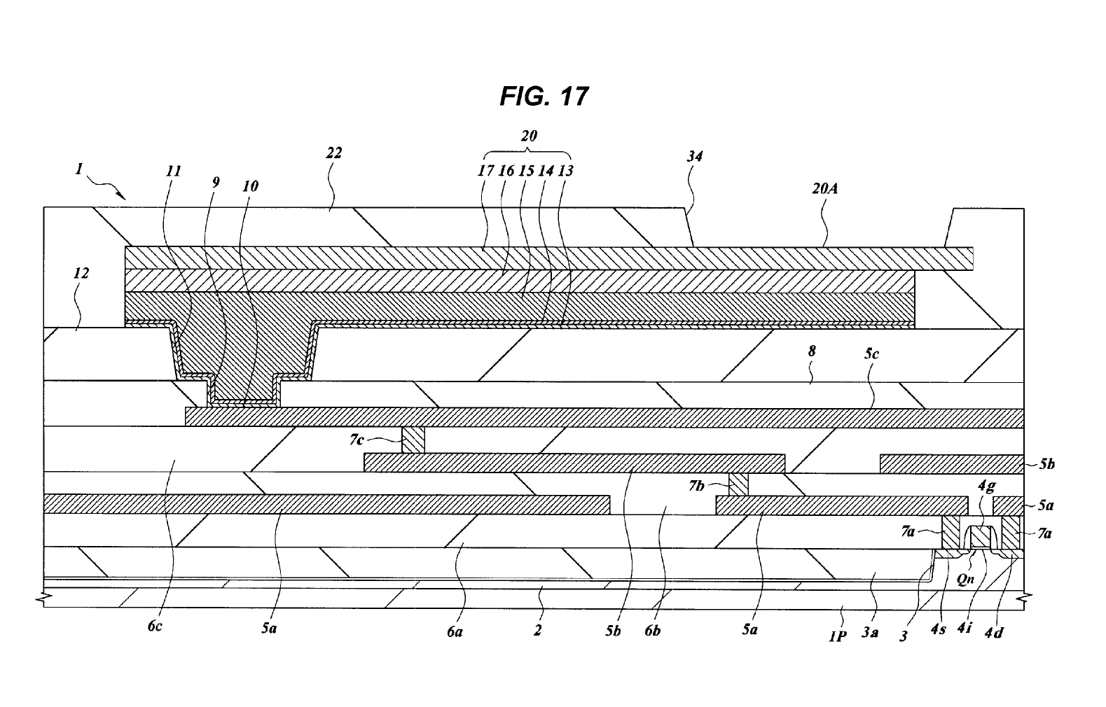

Then, as shown in FIG. 17, the polyimide resin film 22 is subjected to dry etching to form a land opening 34 at the portion to expose the second Ni film 17 at the bottom portion of the land opening 34, forming the land section 20A. By the process up to here, the rewiring 20 is completed. The rewiring 20 is formed by the five layer metal film with lamination of the barrier metal film 13, the seed film 14, the Cu film 15, the first Ni film 16, and the second Ni film 17. In the rewiring 20, the uppermost-layer second Ni film 17 extends outside the other metal films (barrier metal film 13, seed film 14, Cu film 15, and first Ni film 16), at the peripheral portion of the land section 20A.

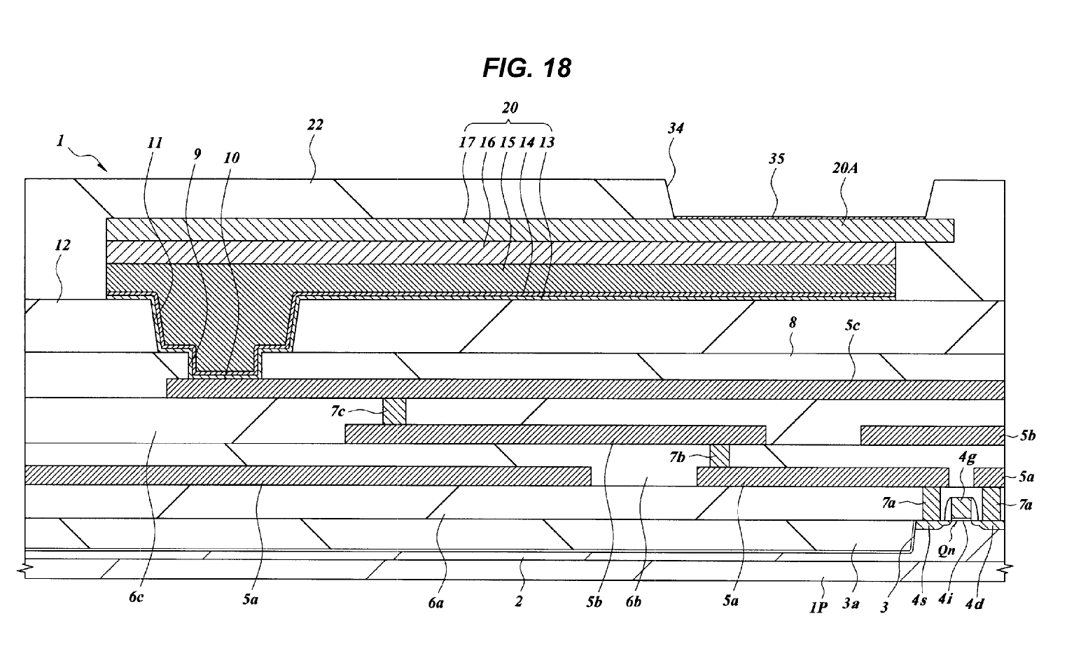

Then, as shown in FIG. 18, as an adhesive film, a gold (Au) film 35 is formed on the surface (the surface of the second Ni film 17) of the land section 20A of the rewiring 20 exposed at the bottom portion of the land opening 34. The Au film 35 is formed to improve the adhesive force between the uppermost layer metal film (second Ni film 17) of the land section 20A of the rewiring 20 and the solder bump 21. The Au film 35 is formed by electroless plating such that the film thickness is approximately 70 to 80 nm. The adhesive film is not limited to the Au film 35, and may be a palladium (Pd) film.

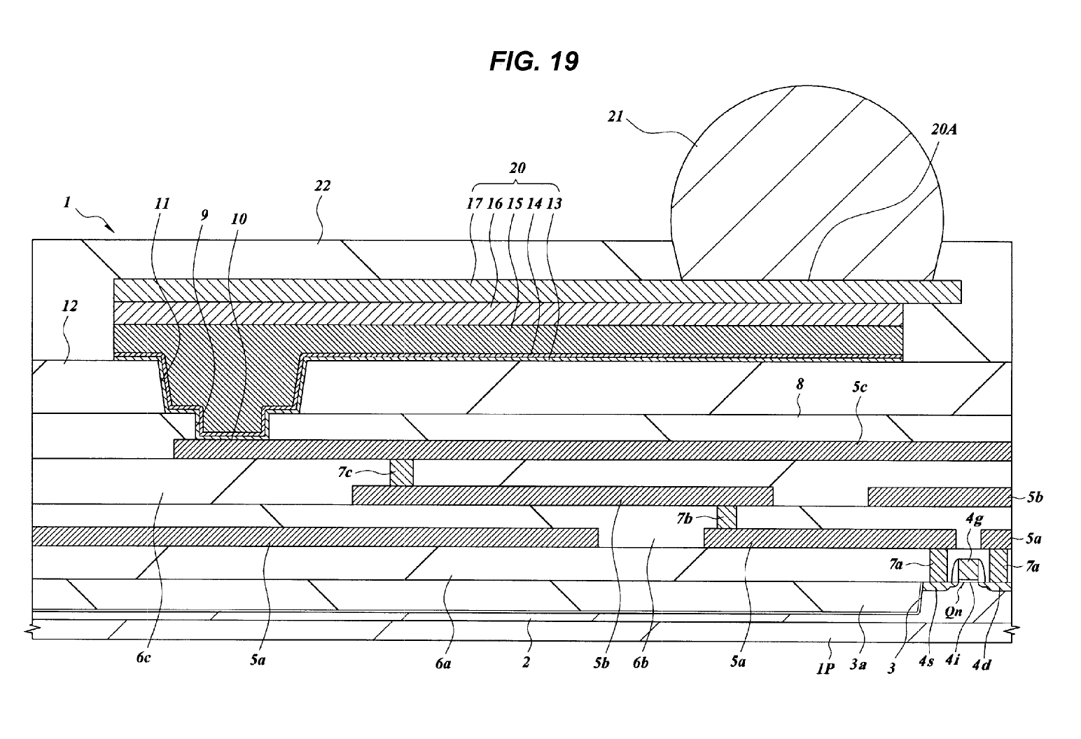

Subsequently, as shown in FIG. 19, by connecting the solder bump (bump electrode) 21 with the surface of the land section 20A, the preprocess (wafer process) for manufacturing a semiconductor integrated circuit device is completed. The solder bump 21 is formed from a known solder material made by adding a minute amount of silver (Ag), copper (Cu), or both to tin (Sn).

To connect the solder bump 21 with the surface of the land section 20A, a known method is employed, such as a method where a solder bump 21 formed in advance in a ball shape is supplied to the surface of the land section 20A and is ref lowed, or a method where a solder material in a paste form is printed on the surface of the land section 20A and is ref lowed. If the solder bump 21 formed in a ball shape or the solder material in a paste form is reflowed, the Au film 35 on the surface of the land section 20A diffuses into the solder bump 21.

Then, to thin the semiconductor wafer 1, its back surface is ground. The purpose of thinning the semiconductor wafer 1 is to thin a semiconductor device (IC package) on which a semiconductor chip 1A obtained from the semiconductor wafer 1 is mounted. To thin the semiconductor wafer 1, the semiconductor wafer 1 is fitted to a scriber (not shown) and its back surface is ground by a grinder. A back grind tape (protection tape) is stuck to the device surface of the semiconductor wafer 1 in advance to prevent the device surface from being contaminated or damaged. This back surface grinding makes the thickness of the semiconductor wafer 1 approximately 150 to 400 μm.

Then, the scribe region of the semiconductor wafer 1 is subjected to dicing so that the semiconductor wafer 1 is singulated into pieces. After the back grind tape is removed from the device surface of the semiconductor wafer 1, the scribe region of the semiconductor wafer 1 is diced by a laser beam, a dicing blade, or the both so that the semiconductor wafer 1 is singulated into pieces. Thus the semiconductor chip 1A, shown in FIGS. 2 to 5, is obtained.

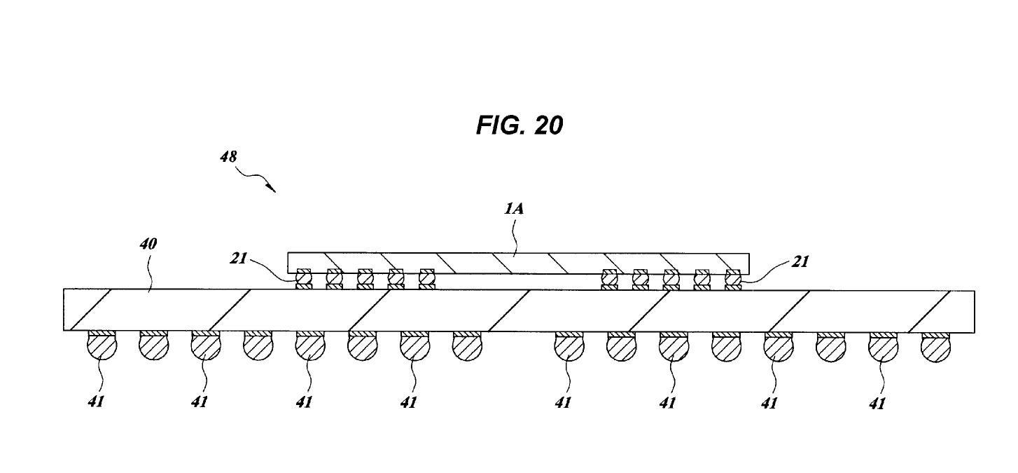

FIG. 20 shows a BGA (ball grid array) type semiconductor device 48 as a mounting structure which mounts the semiconductor chip 1A on the top surface of a wiring substrate 40 through the solder bump (bump electrode) 21. This BGA type semiconductor device 48 is mounted on a mother board or the like of a laptop, which is a mobile electronic device (electronic system), or the like through a plurality of solder bumps (bump electrodes) 41 connected to the lower surface of the wiring substrate 40.

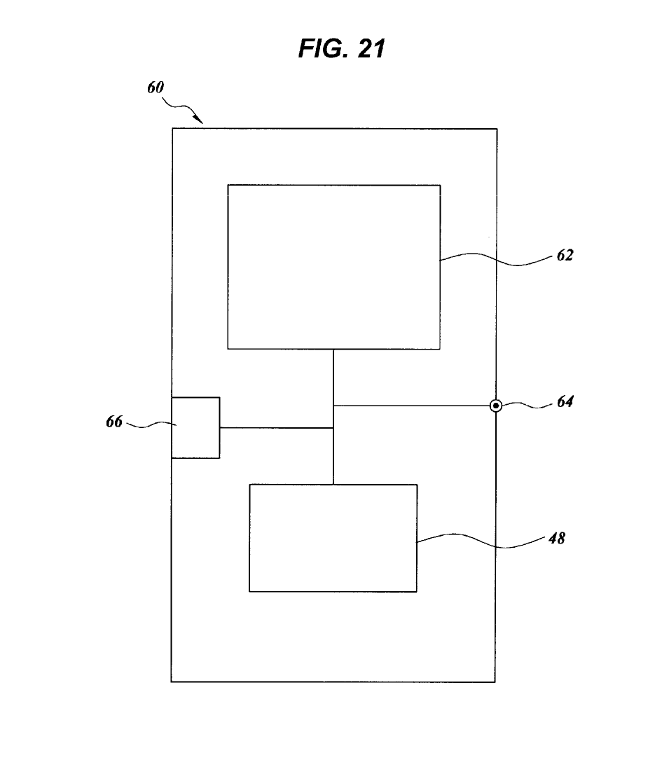

The BGA type semiconductor device 48 is mounted in a mobile electronic device (electronic system) 60 as shown in FIG. 21, such as a laptop, a tablet, or a mobile phone like a smartphone. The mobile electronic device (electronic system) 60 includes a display section 62, such as a liquid crystal display (LCD), a BGA type semiconductor device 48 shown in FIG. 20, and an external connection terminal 64, such as a USB terminal or an input/output terminal. The mobile electronic device (electronic system) 60 is not particularly limited, and may include an information function section 66, such as a flash card function, a CD-ROM function, a DVD function, and a HDD function. The information function section 66 also includes a terminal function to connect these functions. The display section 62, the semiconductor device 48, the external connection terminal 64, and the information function section 66 are electrically connected with each other.

The inventors made a vibration test and a drop shock test on a laptop mounting the BGA type semiconductor device 48 shown in FIG. 20, and confirmed that disconnection does not occur on the solder bump (bump electrode) 21, which connects the semiconductor chip 1A and the wiring substrate 40, even in case that underfill resin is not filled into the gap between the semiconductor chip 1A and the wiring substrate 40.

By making the film thickness of the first layer metal film 20′ of the rewiring 20 larger than that of the second layer metal film (second Ni film 17), and the wiring resistance of the rewiring 20 can be reduced without reduction in the adhesive strength between the rewiring 20 and the bump electrode 21. Thus, even without filling underfill resin into the gap between the semiconductor chip 1A and the wiring substrate 40, disconnection of the solder bump (bump electrode) 21 by vibration or drop shock can be reduced.

The semiconductor integrated circuit device in accordance with the embodiment is not limited to the above-mentioned structures, and various changes and modifications can be made without departing from the spirit of the invention.

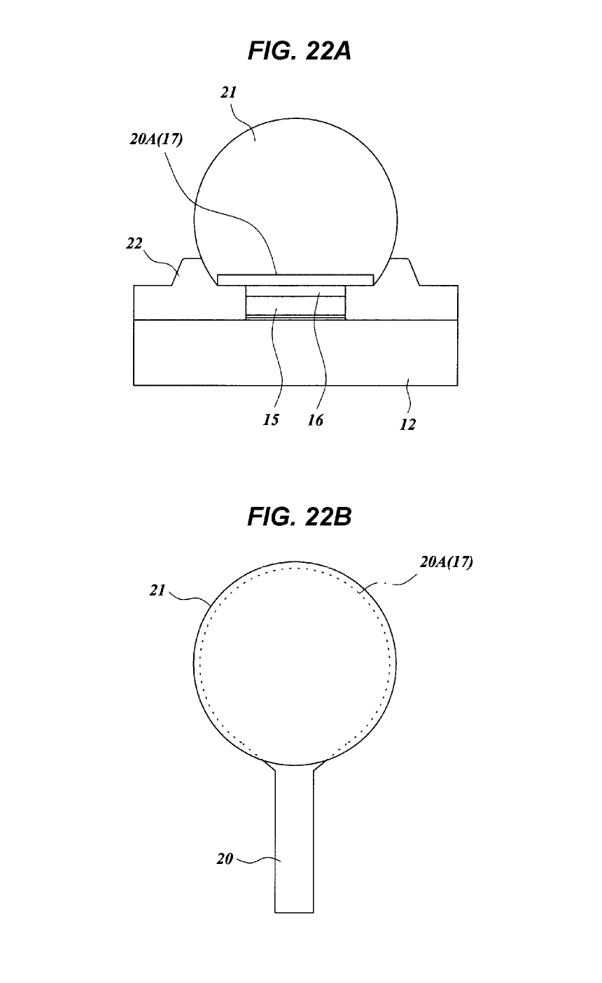

As shown in FIG. 22, the diameter of the solder bump 21 may be made large so that the end portion of the solder bump 21 contacts the side surface of the second Ni film 17. With this arrangement, as the contact area between the solder bump 21 and the land section 20A (second Ni film 17) becomes large, the adhesive strength between them becomes higher further.

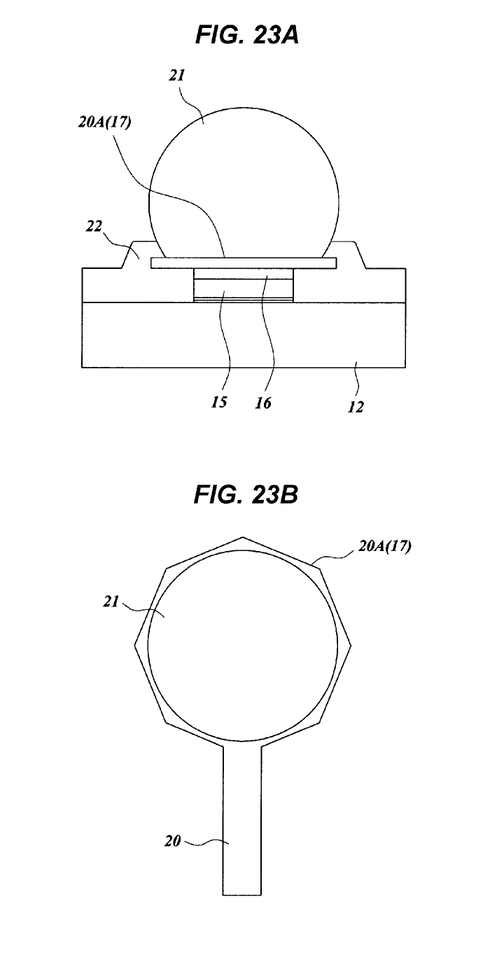

Further, the plane shape of the land section 20A is not limited to a circle, and as shown in FIG. 23, can be a polygon (octagon).

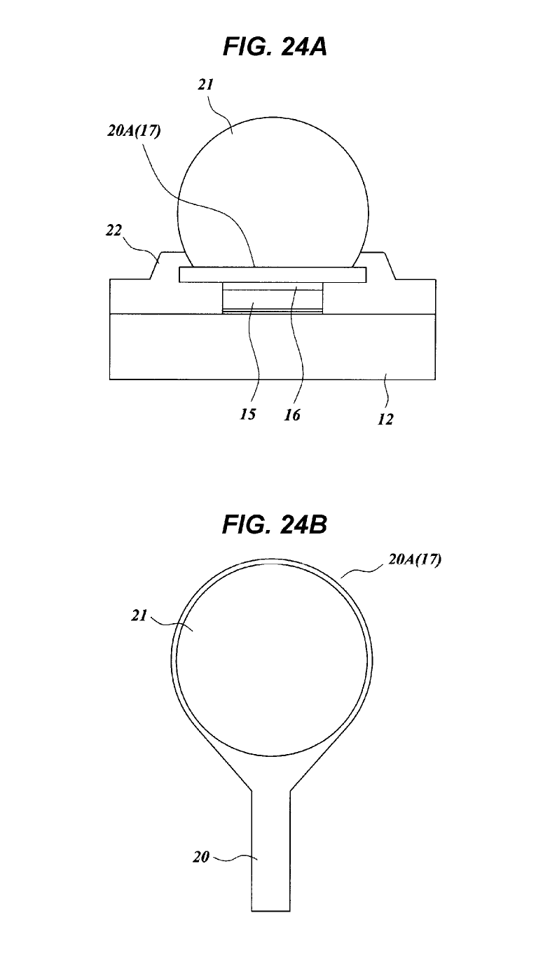

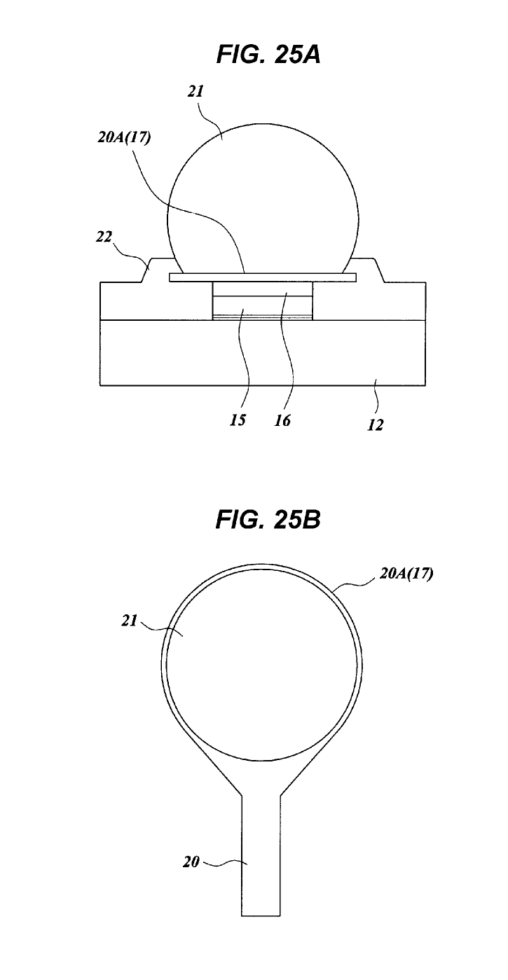

Further, in accordance with the embodiment, of the five layer metal film (barrier metal film 13, seed film 14, Cu film 15, first Ni film 16, and second Ni film 17) forming the rewiring 20, the second Ni film 17 and the first Ni film 16 are formed almost with the same film thickness, but, as shown in FIG. 24, the film thickness of the second Ni film 17 may be made larger than that of the first Ni film 16. Further, in reverse, as shown in FIG. 25, the film thickness of the first Ni film 16 may be made larger than that of the second Ni film 17.

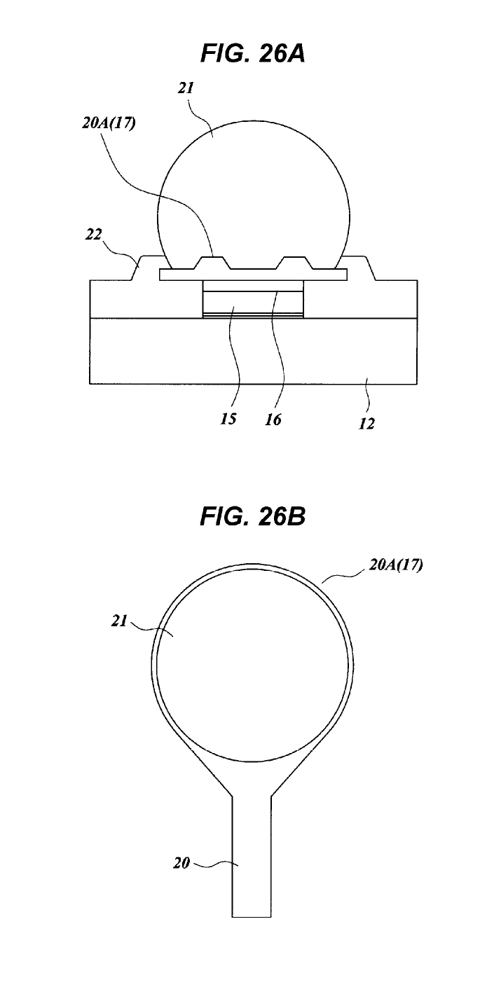

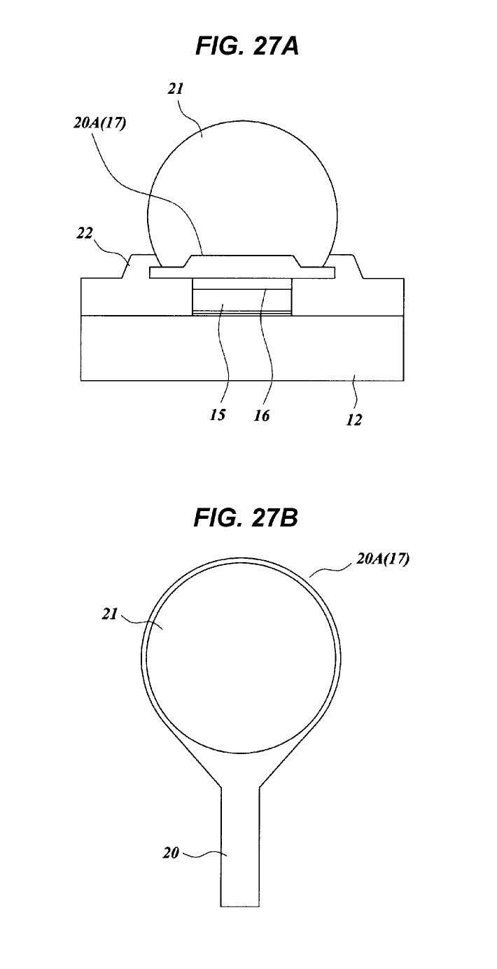

Still further, as shown in FIGS. 26 and 27, the surface of the land section 20A (second Ni film 17) may be partially etched to form a concavo-convex shape. In such a case, as the contact area between the solder bump 21 and the land section 20A (second Ni film 17) becomes large, the adhesive strength between them becomes higher further.

### Embodiment 2

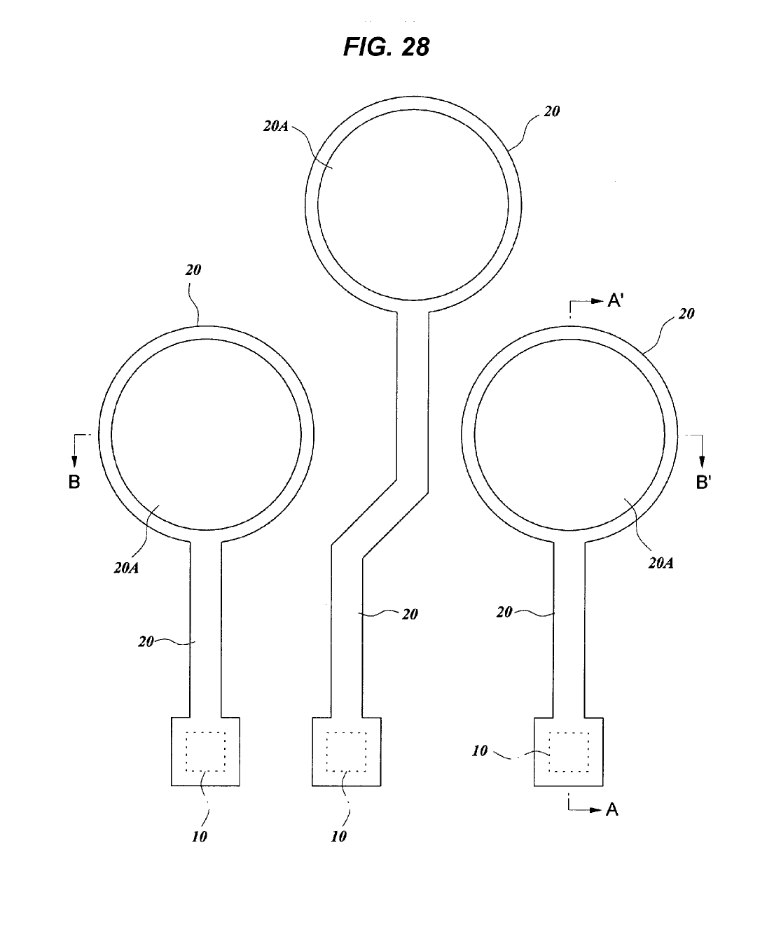

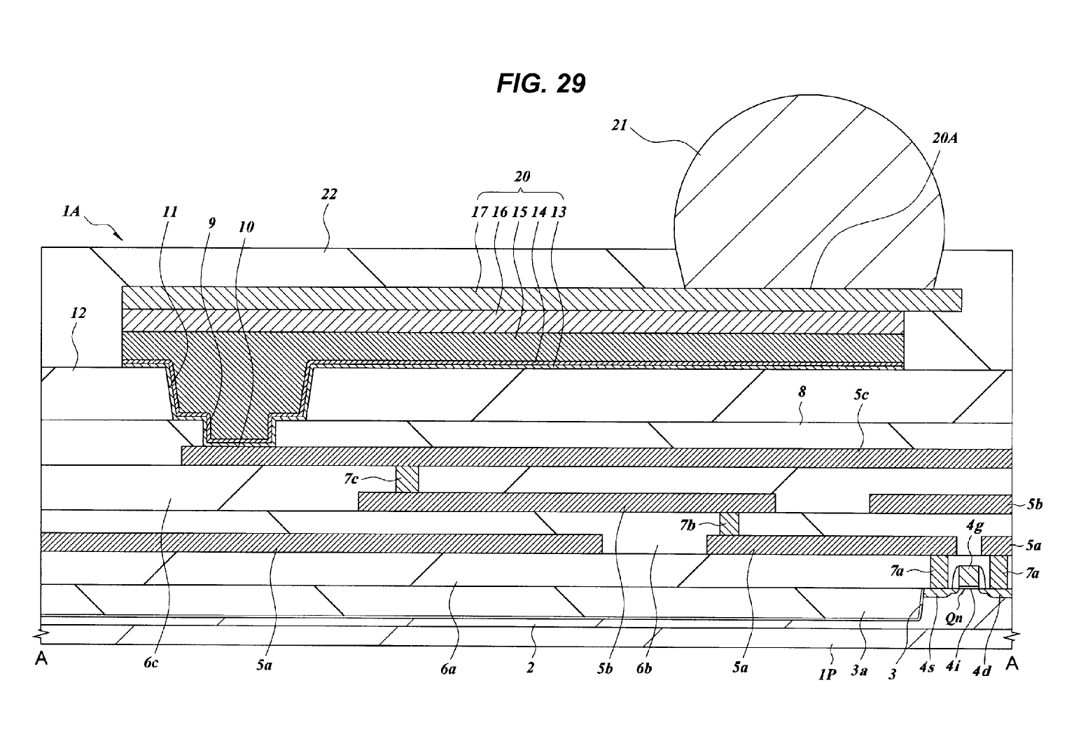

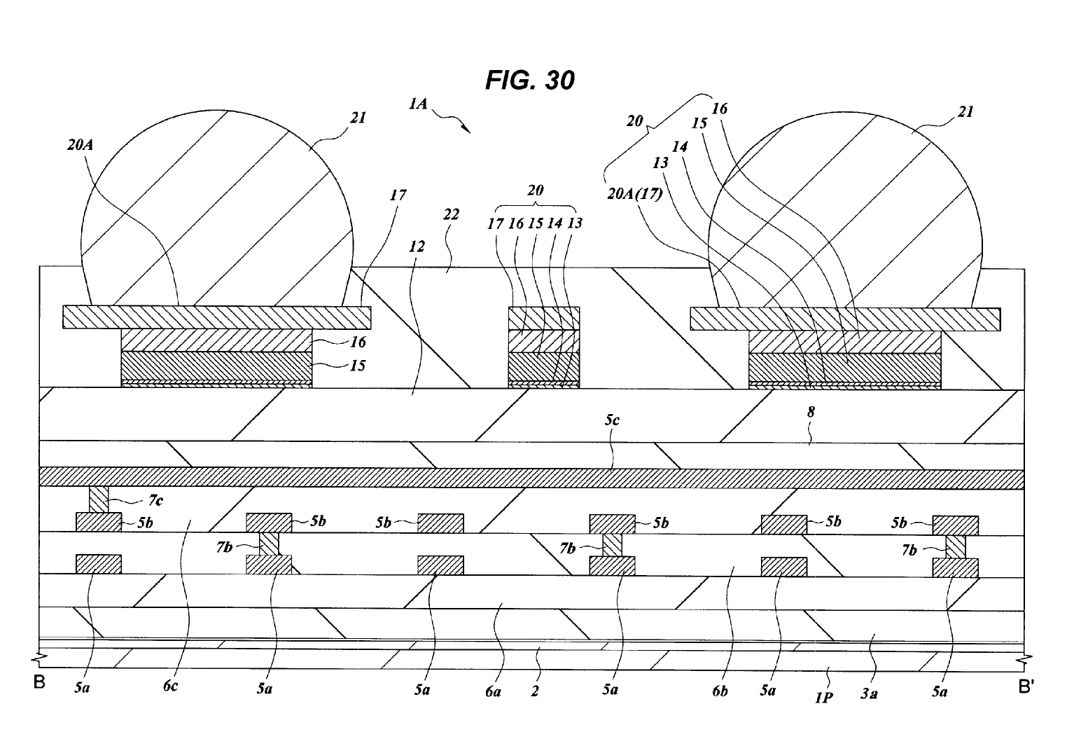

FIG. 28 is a partial enlarged plan view (plan view corresponding to FIG. 3 in Embodiment 1) of a semiconductor integrated circuit device (semiconductor device) in accordance with the embodiment. FIG. 29 is a cross-sectional view taken along line A-A′ in FIG. 28. FIG. 30 is a cross-sectional view taken along line B-B′ in FIG. 28.

In Embodiment 1, only the land section 20A of the rewiring 20 is formed by the five layer metal film (barrier metal film 13, seed film 14, Cu film 15, first Ni film 16, and second Ni film 17), and the other portion (wiring section) is formed by the four layer metal film, namely the first layer metal film 20′ (barrier metal film 13, seed film 14, Cu film 15, and first Ni film 16). However, in accordance with the embodiment, as shown in FIGS. 29 and 30, the entire region of a rewiring 20 including the land section 20A is formed by a five layer metal film (barrier metal film 13, seed film 14, Cu film 15, first Ni film 16, and second Ni film 17). In such a case, the wiring resistances of not only the land section 20A but also the portion (wiring section) other than the land section formation region can be reduced.

In forming the rewiring 20 in accordance with the embodiment, in the opening 32 of the photoresist film pattern 33 shown in FIG. 17, the portion corresponding to the land section 20A of the rewiring 20 is, similarly to Embodiment 1, made larger than the opening 30 of the photoresist film pattern 31, and the portion corresponding to the other portion (wiring section) of the rewiring 20 is made to have the same area as that of the opening 30. So, it is possible to form the second layer metal film (second Ni film 17) also for the portion (wiring section) other than the land section formation region.

Further, similarly to Embodiment 1, also in accordance with the embodiment, various modifications and changes of design can be made, as shown in FIGS. 22 to 27.

Still further, the rewiring structure in Embodiment 1 and the rewiring structure in accordance with the embodiment may be implemented in mixture over the same semiconductor chip 1A. A part of a plurality of rewirings 20 formed on the semiconductor chip 1A may have the rewiring structure in Embodiment 1, and the rest part may have the rewiring structure in accordance with the embodiment.

### Embodiment 3

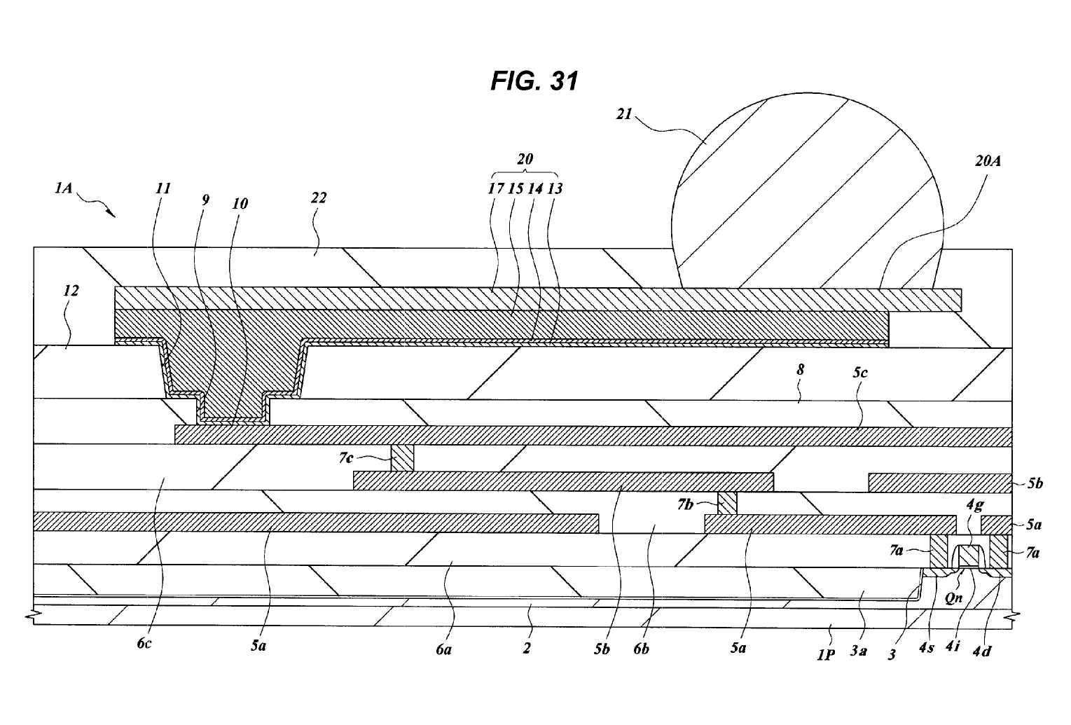

In Embodiments 1 and 2, the rewiring 20 is formed by the five layer metal film (barrier metal film 13, seed film 14, Cu film 15, first Ni film 16, and second Ni film 17), but, as shown in FIG. 31, the first Ni film 16 may be omitted to form the second Ni film 17 directly on the Cu film 15. Alternatively, the second Ni film 17 may be omitted, and the area of the first Ni film 16 of the land section 20A may be made larger than the area of the other metal films (barrier metal film 13, seed film 14, and Cu film 15).

Further, similarly to Embodiment 1, also in the embodiment, various modifications and changes of design, as shown in FIGS. 22 to 27, can be made.

### Embodiment 4

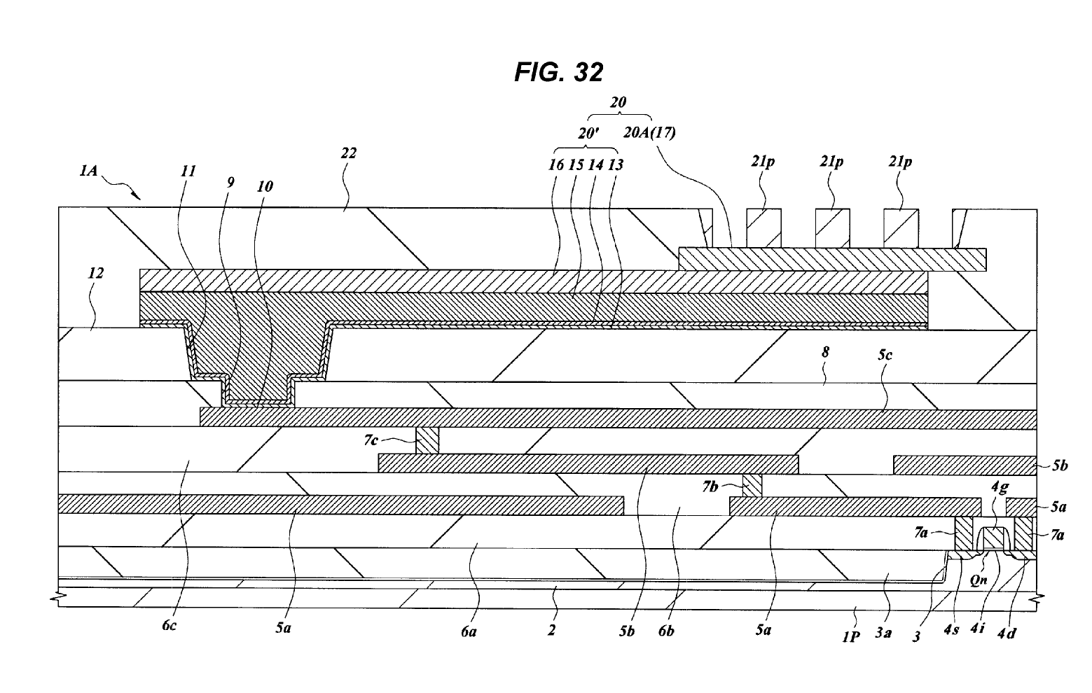

In foregoing Embodiments 1, 2, and 3, the bump electrode (external connection terminal) connected to the land section 20A of the rewiring 20 is formed by the solder bump 21 in a ball shape, but, the bump electrode may be formed by pillar shaped electrodes 21p, as shown in FIG. 32. The pillar shaped electrode 21p is formed from a Cu film containing copper (Cu) as a main component.

The height of the top surface of the pillar shaped electrodes 21p is almost the same as that the of the top surface of the polyimide resin film 22, which is an insulation film, and arrangement is made such that the surface of the semiconductor chip 1A is almost flat. The solder bump (bump electrode) 21 in a ball shape may be further formed on the pillar shaped electrodes 21p.

Further, similarly to Embodiment 1, also in the embodiment, various modifications and changes of design, as shown in FIGS. 22 to 27, can be made.

### Embodiment 5

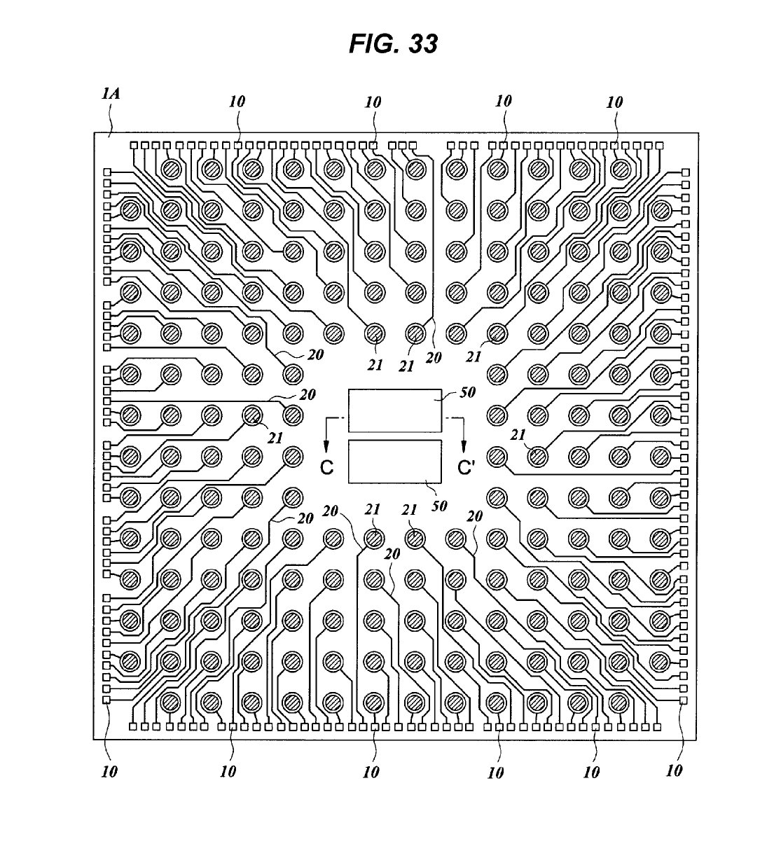

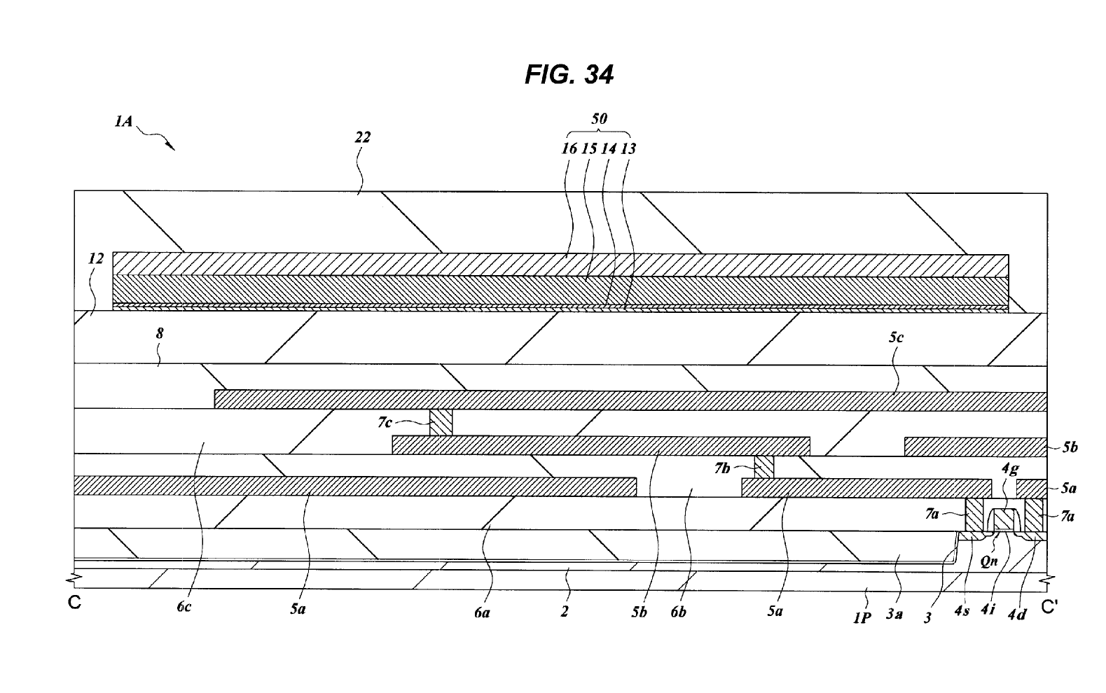

FIG. 33 is an overall plan view of a semiconductor chip formed with a semiconductor integrated circuit device in the present embodiment. FIG. 34 is a cross-sectional view taken along line C-C′ in FIG. 33.

In forming the first layer metal film 20′ (barrier metal film 13, seed film 14, Cu film 15, and first Ni film 16) of the rewiring 20 by using the photoresist film pattern (the first mask) 31 described in Embodiment 1, a dummy pattern 50 may be formed at the upper portion of the polyimide resin film 12, which is an insulation film which the dummy pattern 50 is formed by the first layer metal film 20′ (barrier metal film 13, seed film 14, Cu film 15, and first Ni film 16). It is preferable that the dummy pattern 50 does not function as an active component and is in a state of electrically floating. As shown in FIG. 30, the dummy pattern 50 is disposed in a region where no rewiring 20 is formed or in a region where the density of rewiring 20 is low. A plurality of dummy patterns 50 is disposed in a region where the density of rewiring 20 is low.

As shown in FIG. 34, the dummy pattern 50 has a structure where the second layer metal film (second Ni film 17) is not formed at the upper portion of the first layer metal film 20′, and is formed at the same time in the process of forming the first layer metal film 20′ of the rewiring 20. The side surfaces and the top surface of the dummy pattern 50 are covered by the polyimide resin film 22, which is an insulation film, and the dummy pattern 50 is not exposed at the surface of the semiconductor chip 1A.

Similarly to Embodiment 1, in case that only the land section 20A of the rewiring 20 is formed by the five layer metal film (barrier metal film 13, seed film 14, Cu film 15, first Ni film 16, and second Ni film 17) and the other portion (wiring section) is formed by the first layer metal film 20′ (barrier metal film 13, seed film 14, Cu film 15, and first Ni film 16), the unevenness in the density of wiring sections (first layer metal film 20′) in the plane of semiconductor chip 1A becomes higher, as shown in FIG. 2. Further, as the film thickness of the second layer metal film (second Ni film 17) is smaller than that of the first layer metal film 20′, if the first layer metal film 20′ and the second layer metal film (second Ni film 17) are formed by electrolytic plating, unevenness in the film thickness by plating in the wafer plane becomes higher for the first layer metal film 20′ than for the second layer metal film (second Ni film 17).

Accordingly, by disposing, in a region where the density of rewiring 20 is low, a plurality of dummy patterns 50 formed by the first layer metal film 20′, the unevenness in the film thickness by plating in the wafer plane can be reduced in forming the Cu films 15 and the first Ni films 16, which are conductive films forming the rewiring 20. Thus, the reliability of a semiconductor integrated circuit device (semiconductor device) can be improved, and the properties of the semiconductor device can be improved.

Dummy patterns 50 may be provided in a scribe region of a semiconductor wafer. In the periphery of a semiconductor chip, a seal ring wiring formed by a multi-layer wiring is disposed to surround the integrated circuit formation region, and in this situation, dummy patterns 50 may be disposed in the scribe region, which is on the outside of the region where the seal ring wiring is disposed. In this case, the dummy patterns 50 may be formed in the entire scribe region and may be formed only near the seal ring wiring.

Further, it is also possible to form an alignment mark for aligning a mask, using the dummy patterns 50.

In such a manner, arranging the dummy patterns 50 with a structure where the second layer metal film (second Ni film 17) is not formed at the upper portion of the first layer metal film 20′ is a new feature in addition to the above-mentioned and other purposes of the present invention.

Further, various modifications and changes in design, as shown in FIGS. 22 to 27, can also be made on the dummy patterns 50.

### Embodiment 6

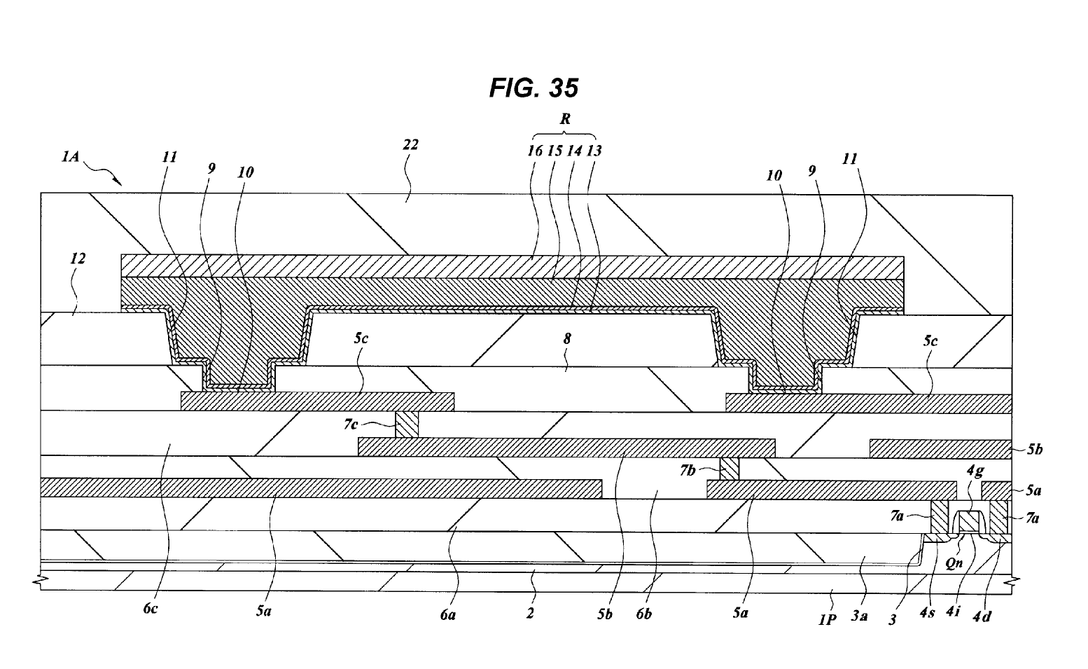

FIG. 35 is a partial enlarged cross-sectional view of a semiconductor chip formed with a semiconductor integrated circuit device in accordance with the embodiment.

In forming the first layer metal film 20′ (barrier metal film 13, seed film 14, Cu film 15, and first Ni film 16) of the rewiring 20 by using the photoresist film pattern 31 (the first mask) described in Embodiment 1, a resistor element R constructed with the first layered metal film 20′ (the barrier metal film 13, the seed film 14, the Cu film 15, and the first Ni film 16) may be formed on the polyimide resin film 12, which is an insulation film.

As shown in FIG. 35, the resistance element R is formed with a structure where the second layer metal film (second Ni film 17) is not formed at the upper portion of the first layer metal film 20′, and is formed at the same time in the process of forming the first layer metal film 20′ of the rewiring 20. The top surface and the side surfaces of the resistance element R are covered by the polyimide resin film 22, which is an insulation film, and the resistance element R is not exposed at the surface of the semiconductor chip 1A.

Further, though not shown, in forming the first layer metal film 20′ (barrier metal film 13, seed film 14, Cu film 15, and first Ni film 16) of the rewiring 20, an inductance element formed by the first layer metal film 20′ may be formed, or a capacitance element having the first layer metal film 20′ as one electrode and the third layer wiring 5c as the other electrode may be formed.

By forming passive components, such as a resistance element R, an inductance element, or a capacitance element by using the first layer metal film 20′ of the rewiring 20, unevenness in the properties of elements can be reduced, and the properties of a semiconductor integrated circuit device (semiconductor device) can be improved. Further, the chip size can be easily reduced without adding a new manufacturing process.

Arranging a passive component with a structure where the second layer metal film (second Ni film 17) is not formed at the upper portion of the first layer metal film 20′ is a new feature in addition to the above-mentioned and other purposes of the present invention.

Further, various modifications and changes, as shown in FIGS. 22 to 27, on the passive components also can be made.

### Embodiment 7

In Embodiment 1, a stress reducing structure of a solder bump 21 connected to the land section 20A of the rewiring 20 is described, but, in the embodiment, an application to a structure for reducing bonding damage in connecting an external connection terminal (wiring) with the rewiring 20, using a wiring bonding method, will be described.

In case that the external connection terminal is formed by a wiring instead of the solder bump (bump electrode) 21, a rewiring 20 is formed by a structure where the second layer metal film (the second Ni film 17) is not formed at the upper portion of the first layer metal film 20′. Further, polyimide resin film 22 is not formed on the top surface or the side surfaces of this rewiring 20. The rewiring 20 is formed in a state that the rewiring 20 is exposed at the surface of the semiconductor chip 1A.

Further, the semiconductor chip 1A formed with such a rewiring 20 is sealed with a synthetic resin, such as epoxy resin, to configure a plastic package. For such a package, as it is required to make the thickness of the package small, it is desirable that a polyimide resin film 12 is not formed under the rewiring 20. It is desirable to form the rewiring 20 directly on the surface protection film (final passivation film) 8.

However, as the rewiring 20 is disposed above an integrated circuit formed on the device surface of the semiconductor chip 1A, if an insulation film, such as a polyimide resin film 12, is not provided between the surface protection film 8 and the rewiring 20, wiring bonding damage to the integrated circuit becomes significant, with a possibility to cause drop in the reliability of the semiconductor integrated circuit device and drop in the properties of elements. Further, a semiconductor integrated circuit device that uses a low dielectric film (low-k film) with an dielectric constant lower than that of a silicon oxide film, as the inter-layer insulation film to be arranged at the lower portion of the surface protection film 8, possibly causes drop in the reliability and drop in the element properties, because the strength of the inter-layer insulation film is low.

In the embodiment, wiring bonding damage is reduced by a structure described below.

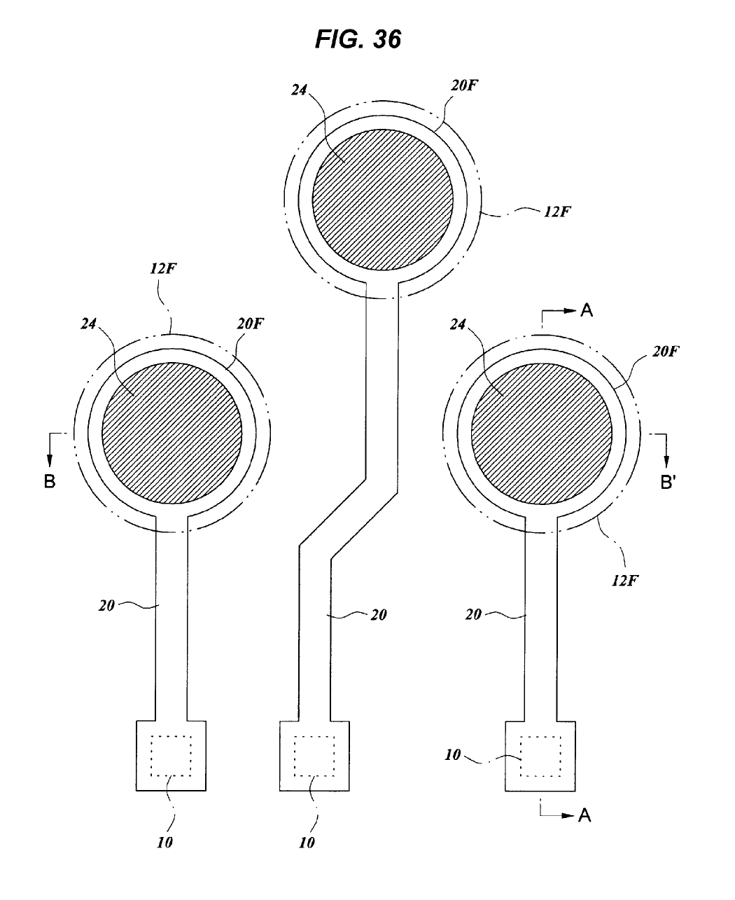

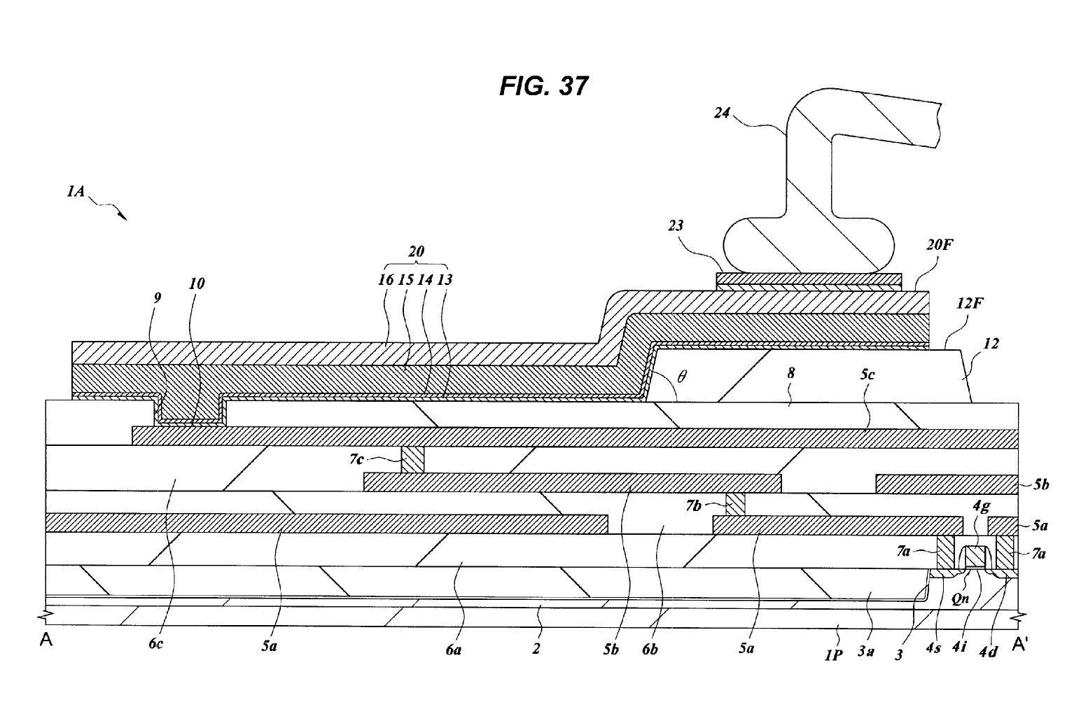

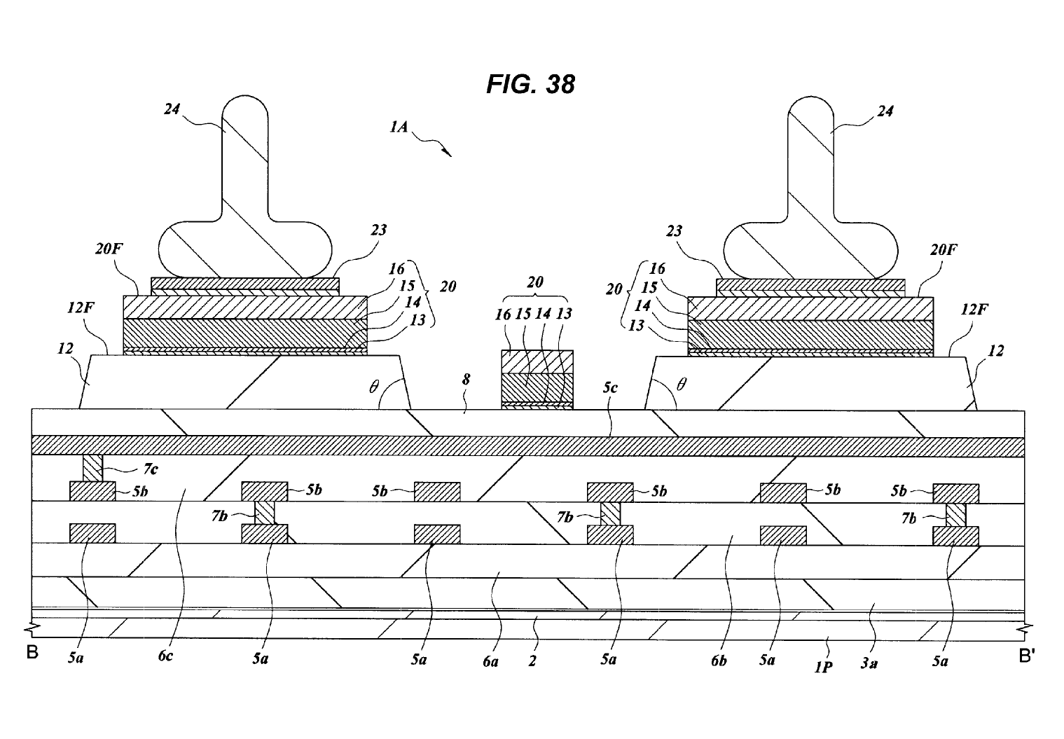

FIG. 36 is a partial enlarged plan view of a semiconductor chip in accordance with the embodiment. FIG. 37 is a cross-sectional view taken along line A-A′ in FIG. 36. FIG. 38 is a cross-sectional view taken along line B-B′ in FIG. 36.

As shown in FIGS. 36 to 38, the rewiring 20 is formed at the upper portion of the surface protection film (final passivation film) 8, and the first end is electrically connected to a pad 10 through the pad opening 9 of the surface protection film 8. Further, a bonding region (coupling region) provided at the second end of the rewiring 20 is electrically connected with a wiring 24 of gold (Au) or copper (Cu) through a bonding layer 23 formed on the top surface of the rewiring 20.

The bonding layer 23 formed in the bonding region of the rewiring 20 is formed by a two-layer film of a nickel (Ni) film and a gold (Au) film laminated at the upper portion of the nickel (Ni) film. The Ni film, which is the lower layer film of the bonding layer 23, is formed to improve the adhesiveness between the surface (first Ni film 16) of the rewiring 20 and the bonding layer 23. Further, the Au film, which is the upper layer film of the bonding layer 23, is formed to improve the adhesiveness between the wiring 24 and the bonding layer 23.

A polyimide resin film 12, which is an insulation film, is formed at the lower portion of the bonding region of the rewiring 20. The polyimide resin film 12 is not formed at the lower portion of the other portion (wiring section), excluding the bonding region of the rewiring 20. The polyimide resin film 12 is selectively formed only at the lower portion of the bonding region of the rewiring 20.

Symbol 20F represents a region (flat section) where the surface of the rewiring 20 is flat, and the bonding region (connecting region) in consideration of aligning dimensions for wiring bonding is positioned inside the flat section 20F. That is, the wiring 24 is electrically connected with the rewiring 20 in the bonding region positioned inside the flat section 20F of the rewiring 20.

Further, symbol 12F represents a region (flat section) where the surface of the polyimide resin film 12 is flat. The flat section 12F of the polyimide resin film 12 is disposed to overlap, in plan view, with the flat section 20F of the rewiring 20, and is formed to have a diameter larger than that of the flat section 20F of the rewiring 20. Accordingly, the bonding region of the rewiring 20 is positioned, in plan view, inside the flat section 12F of the polyimide resin film 12. Further, the flat section 12F of the polyimide resin film 12 is disposed to, in plan view, overlap with the bonding layer 23 formed on the top surface of rewiring 20, and is formed to have a diameter larger than that of the bonding layer 23. As described above, the polyimide resin film 12 is formed with a film thickness larger than that of the surface protection film 8.

The side surface of the polyimide resin film 12 is provided with a taper angle (θ) to prevent the side surfaces of the polyimide resin film 12 from becoming a rapid step. It is possible to prevent a rapid change in level for the rewiring 20 formed at a side surface of the polyimide resin film 12. Thus, it is possible to reduce an increase in the resistance of the rewiring 20.

By forming the polyimide resin film 12 at the lower portion of the bonding region of the rewiring 20, bonding damage through connecting the rewiring 20 with the wiring 24 is absorbed by the polyimide resin film 12, and wiring bonding damage to the integrated circuit is reduced. Thus, it is possible to reduce a drop in reliability of the semiconductor integrated circuit device and a drop in the element properties.

Further, the polyimide resin film 12 is selectively formed only at the lower portion of the bonding region of the rewiring 20, and is not formed in other regions. The rewiring 20 is formed directly on the surface protection film 8 except the bonding region. Thus, compared with a case that the polyimide resin film 12 is formed on the entire surface of the semiconductor chip 1A, because the thickness of the semiconductor chip 1A is smaller, the thickness of a package in which this semiconductor chip 1A is resin-sealed can be made smaller.

Further, in case of forming a fuse element by using a wiring layer with the above-mentioned multi-layer wiring structure and melting and cutting the fuse element with a laser or the like, an opening is provided through the inter-layer insulation film formed at the lower portion of the surface protection film 8. Through the opening, the fuse element is melted and cut by irradiation with a laser to perform trimming, relieving a memory defect, or the like. After the trimming, the polyimide resin film 12 is left to cover the opening, and then the reliability of the semiconductor integrated circuit device can be improved.

As described above, the bonding layer 23 formed on the top surface of the rewiring 20 is formed by a two-layer film in lamination of an Au film at the upper portion of a Ni film, but, the Au film, which is the upper layer film of the bonding layer 23, has poorer adhesiveness with resin, compared with the Ni film, which is the lower layer film, and the first Ni film 16 on the surface of the rewiring 20. Therefore, if the bonding layer 23 is formed on the entire top surface of the rewiring 20, the adhesiveness between the resin and the rewiring 20 drops, and the reliability of the package drops. In the embodiment, as the bonding layer 23 is selectively formed on a part (bonding region) of the top surface of the rewiring 20, arrangement is made to reduce a drop in adhesiveness between the resin and the rewiring 20.

Further, in the process of manufacturing a package in which the semiconductor chip 1A is sealed, to make the thickness of the package small, a task (film thinning process) for thinning a semiconductor wafer is performed before a wiring bonding process. In the film thinning process of a semiconductor chip wafer by grinding with a grinder the back surface of the semiconductor wafer for which the preprocess (wafer process) has been completed, the semiconductor chip 1A after dicing is thinned.

In the above-mentioned film thinning process, when aback grind tape is attached to the device surface of the semiconductor chip 1A, the back grind tape is also attached to the top surface of the bonding layer 23 (refer to FIGS. 35 and 36) formed on the top surface of rewiring 20. Accordingly, if the adhesive force between the rewiring 20 and the bonding layer 23 is low, when the back grind tape is peeled off from the device surface of the semiconductor wafer after grinding of the back surface, the bonding layer 23 possibly peels off from the surface of the rewiring 20. Then, the bonding layer 23 having peeled off causes an adverse effect of wiring bonding which the peeling-portion of the bonding layer 23 bends to overlap on the non-peeling portion of the bonding layer 23.

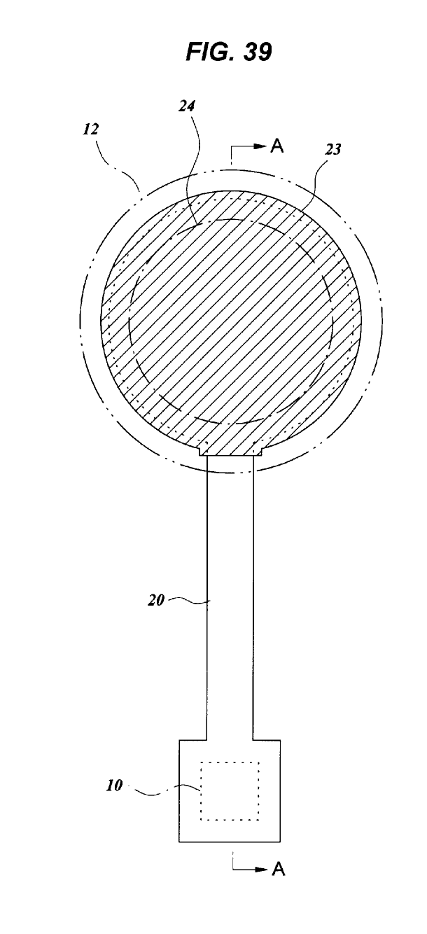

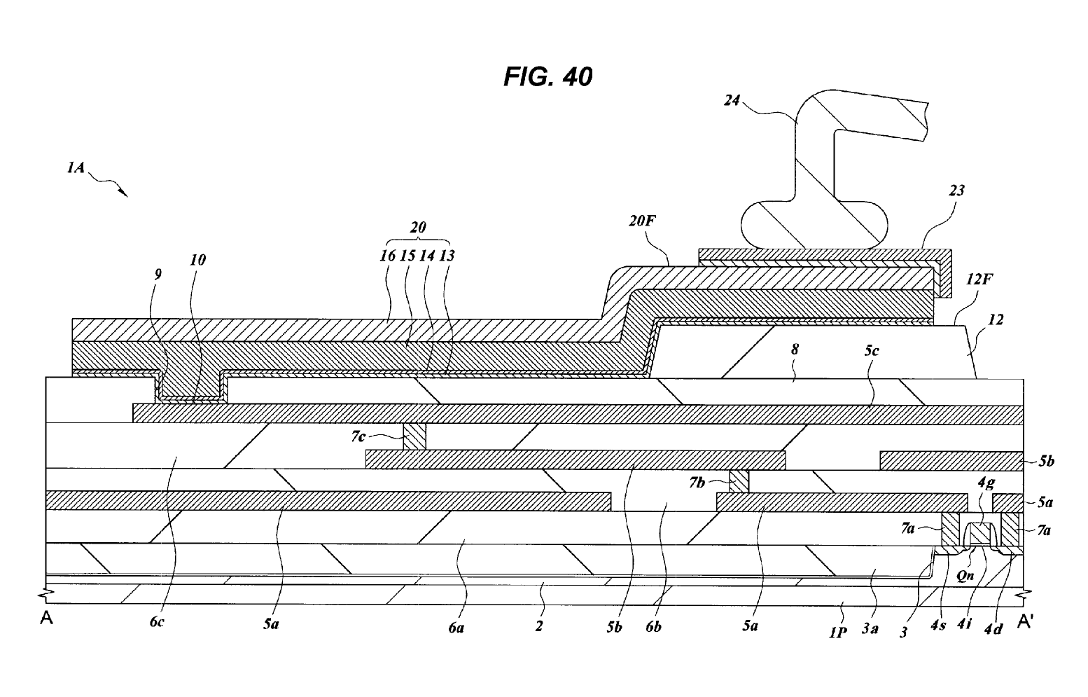

To improve the adhesive force between the rewiring 20 and the bonding layer 23 formed on the top surface, as shown in FIGS. 39 and 40 (the cross-sectional view taken along A-A in FIG. 39), it is effective to integrally form the bonding layer 23 such that it covers the top surface and the side surface of the rewiring 15.

In this case, not only the contact area between the bonding layer 23 and the rewiring 15 increases but also the bonding layer 23 formed on the side surface of the rewiring 15 does not contact with the back grind tape when the back grind tape is attached to the device surface of the semiconductor chip 1A. Because the adhesive force between the rewiring 20 and the bonding layer 23 is improved, it is possible to reduce occurrence of the defect that the bonding layer 23 peels off from the surface of the rewiring 20 in the film thinning process of the semiconductor chip 1A.

A manufacturing method of a semiconductor integrated circuit device in the embodiment will be described below. A case where the bonding layer 23 is integrally formed to cover the top surface and the side surface of the rewiring 15 will be described below, but, a semiconductor integrated circuit device (refer to FIGS. 36 to 38) in which a bonding layer 23 is formed only on the top surface of the rewiring 15 can also be manufactured by a method based on the manufacturing method described below.

First, a pad opening 9 is formed in the surface protection film 8, according to the process, shown in FIGS. 7 and 8 for Embodiment 1, and a pad 10 is formed by making a portion of the third layer wiring 5c exposed.

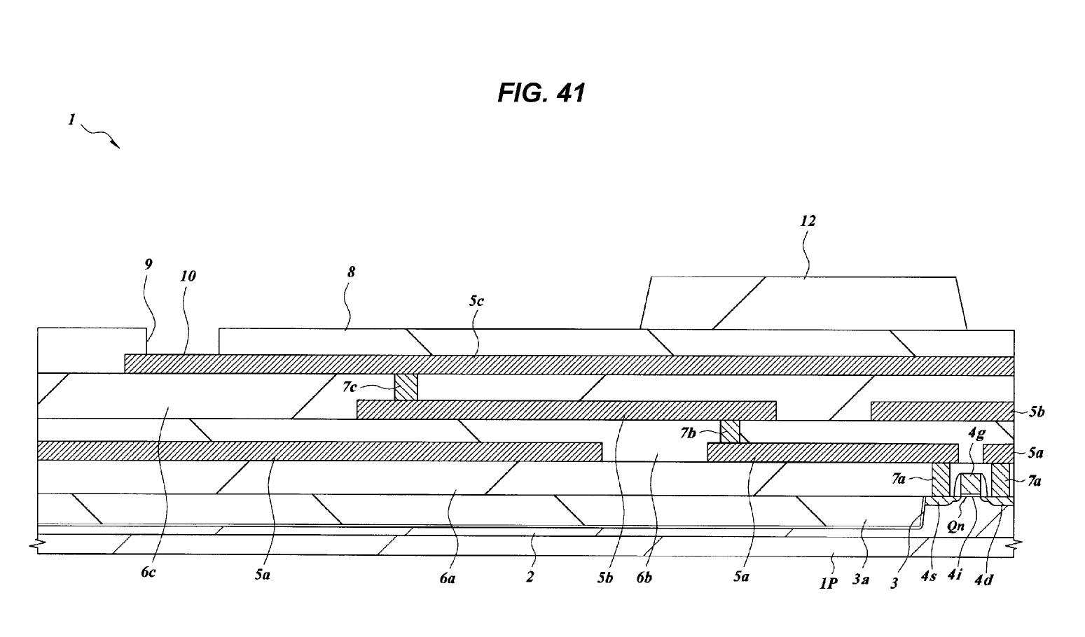

Then, as shown in FIG. 41, after forming a polyimide resin film 12 at the upper portion of the surface protection film 8, the polyimide resin film 12 is subjected to patterning by dry etching using a photoresist film as a mask, and the polyimide resin film 12 is selectively left in the region where the bonding region of the rewiring 20 will be disposed in a later process.

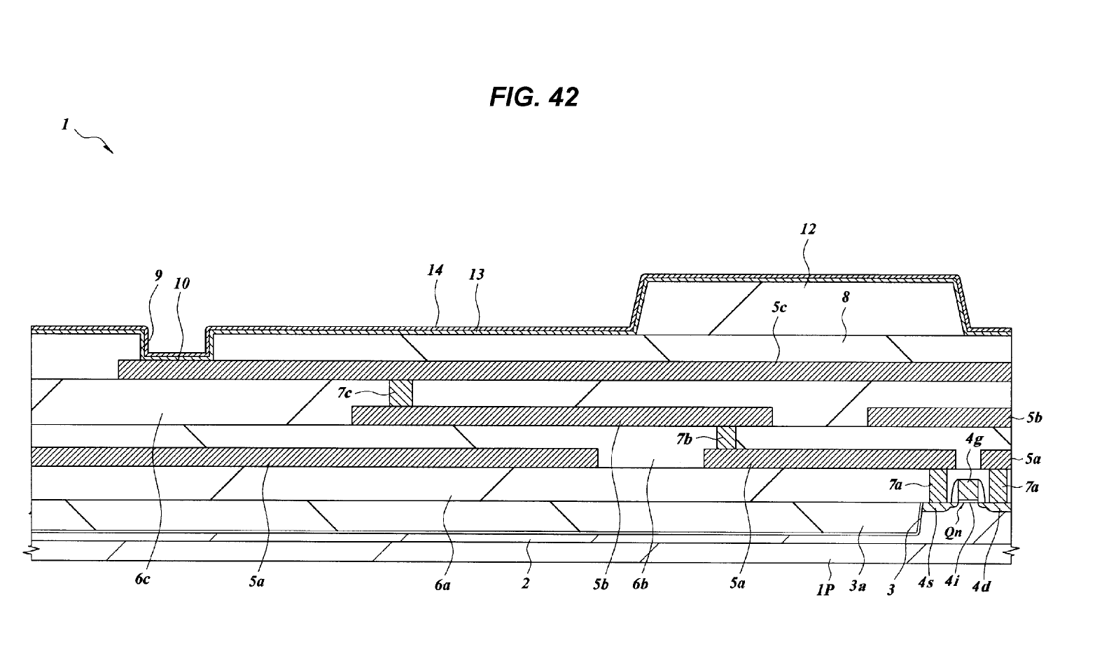

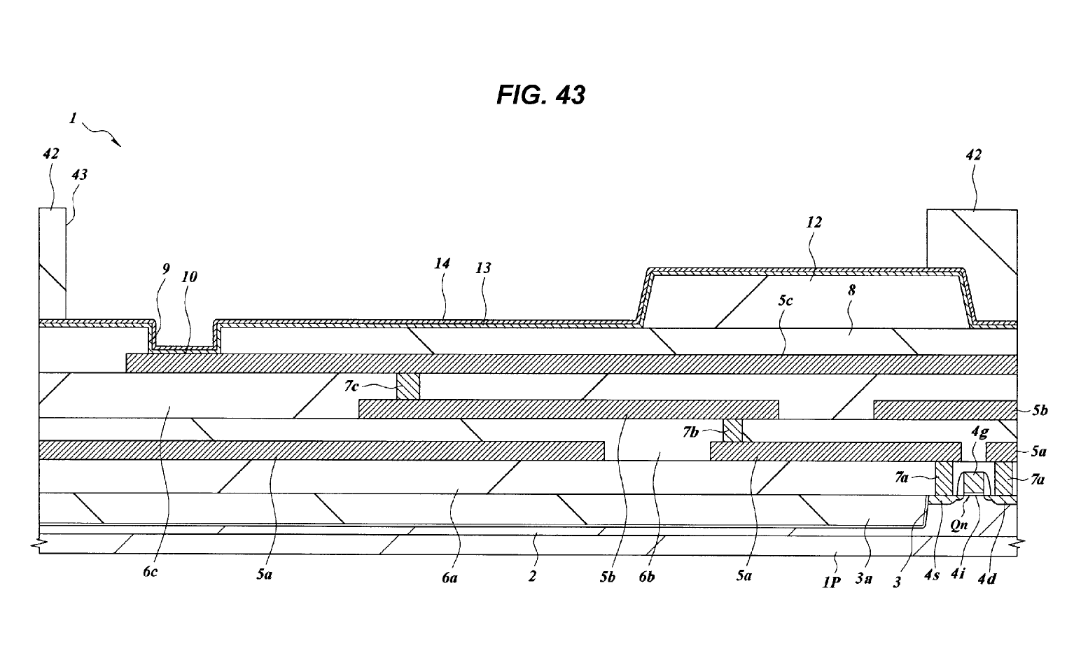

Then, as shown in FIG. 42, the barrier metal film 13 and the seed film 14 are sequentially disposed on the entire surface of the semiconductor wafer 1 by sputtering. Subsequently, as shown in FIG. 43, a photoresist film is deposited on the entire surface of the semiconductor wafer 1. This photoresist film is exposed and developed and then a photoresist film pattern (the first mask) 42 having an opening 43 at the part is formed.

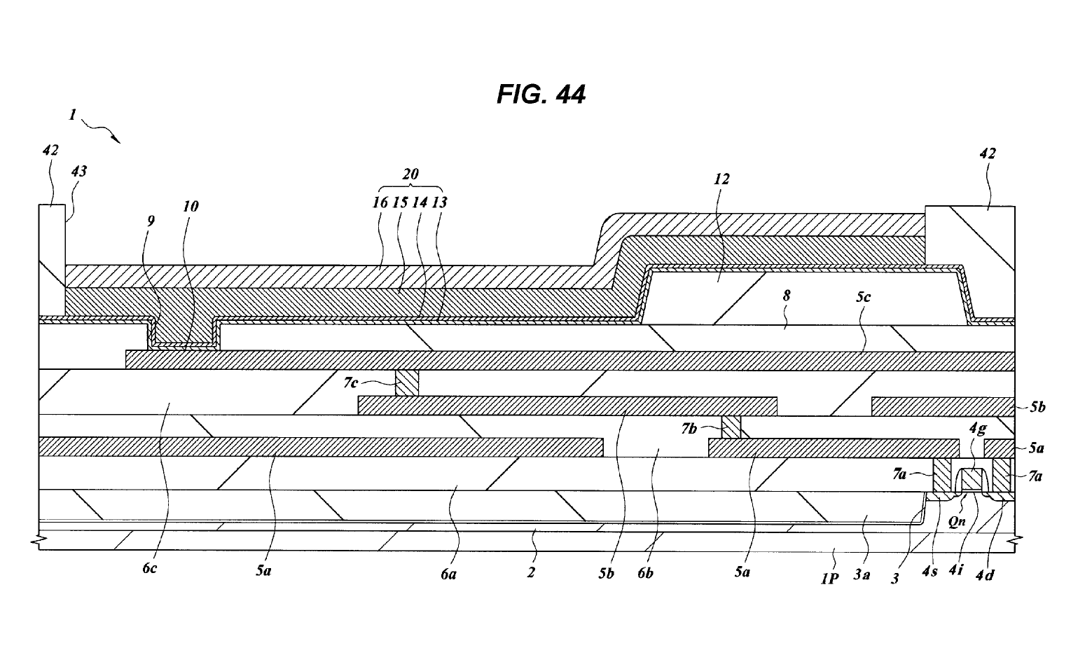

Then, as shown in FIG. 44, the Cu film 15 is deposited by electrolytic plating on the surface of the seed film 14 exposed at the bottom of the opening 43 of the photoresist film pattern 42. Subsequently, the first Ni film 16 is deposited on the surface of the Cu film 15.

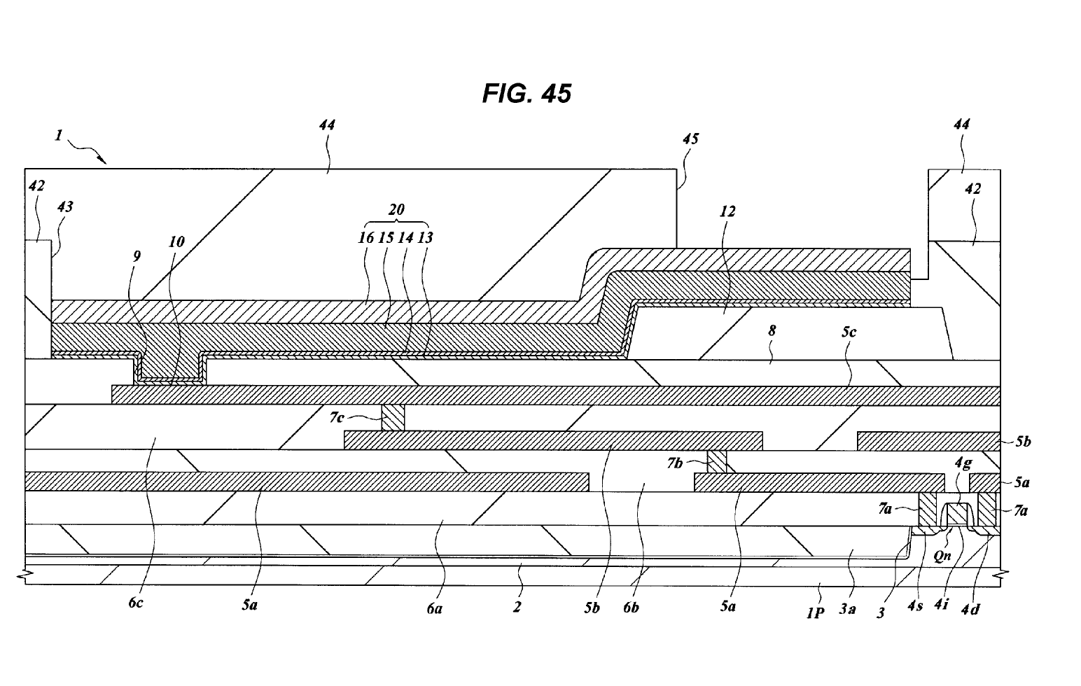

Then, as shown in FIG. 45, in a state that the photoresist film pattern 42 is left, a photoresist film is deposited on the entire surface of the semiconductor wafer 1, and this photoresist film is exposed and developed to form a photoresist film pattern (the second mask) 44 having an opening 45 at a portion of it. By also exposing and developing then a portion of the photoresist film pattern 42 formed under the photoresist film pattern 44, a portion of the top surface and a portion of the side surface of the rewiring 15 are exposed at the bottom of the opening 45.

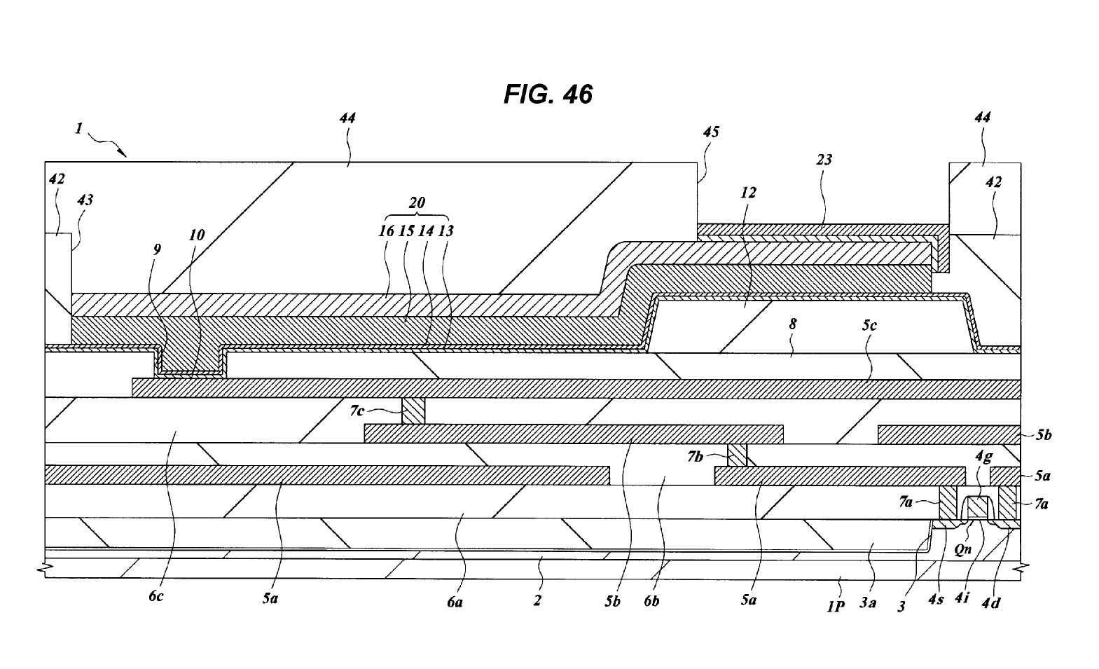

Then, as shown in FIG. 46, on the top surface and the side surface of the rewiring 15 exposed at the bottom of the opening 45 of the photoresist film pattern 44, a bonding layer 23 formed by a two-layer film consisting of a Ni film and an Au film is formed by electrolytic plating.

Then, the two-layer photoresist film patterns 42 and 44 having become unnecessary are removed by solvent or ashing, and subsequently, the seed film 14 and the barrier metal film 13, which are exposed in the region from which the photoresist film pattern 42 has been removed and are unnecessary, are removed by wet etching.

Subsequently, the semiconductor wafer is diced through the film thinning process of a semiconductor wafer; a wiring 24 is connected to the rewiring 20 of the obtained semiconductor chip 1A; and then the semiconductor chip 1A, shown in FIGS. 39 and 40, is completed. Connection of the wiring 24 is performed by a ball bonding method where an ultrasonic wave is applied, or heat and an ultrasonic wave are applied at the same time.

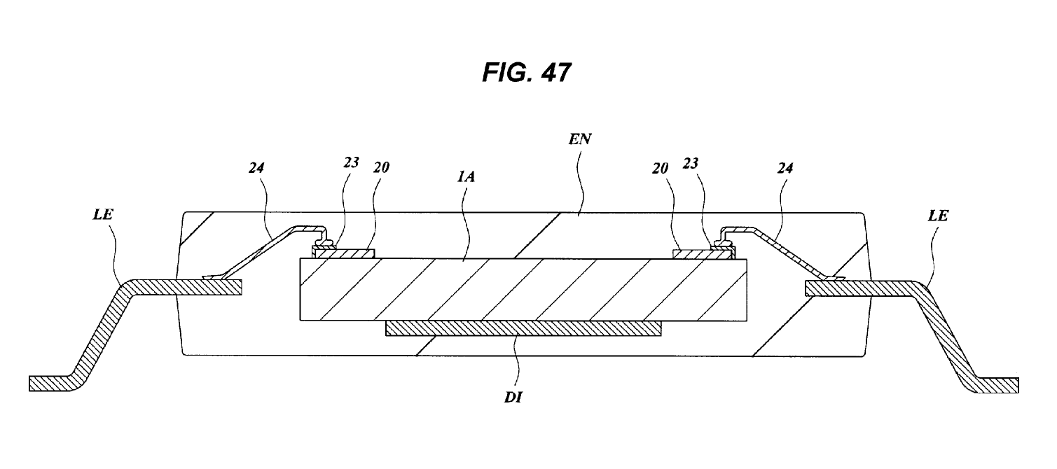

Subsequently, as shown in FIG. 47, through a packaging process that seals a portion (inner lead) of a lead LE, a die pad section DI, the semiconductor chip 1A, and the wiring 24 with a resin (sealing resin) EN, such as a thermoset epoxy resin, the semiconductor integrated circuit device (semiconductor device) in accordance with the embodiment is completed.

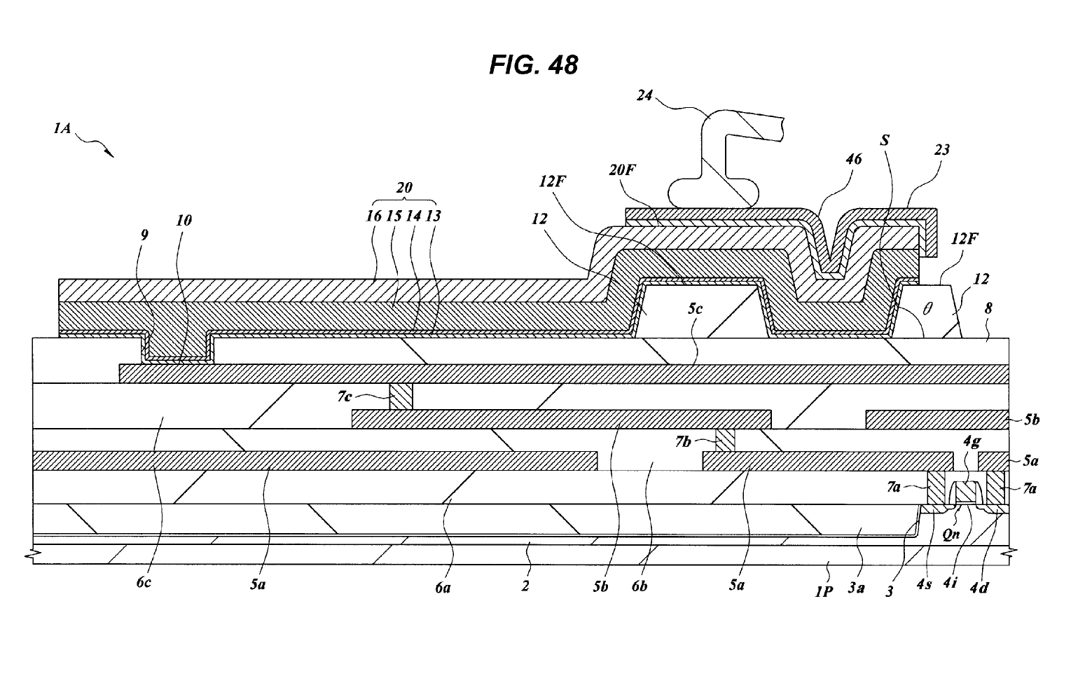

To further improve the adhesive force between the rewiring 20 and the bonding layer 23 formed on it, as shown in FIG. 48, a slit S having a taper angle (θ) at the side surface may be provided for the polyimide resin film 12 located at a position outside the bonding region of the rewiring 20. This slit S is desirably provided in a ring shape in plan view to surround the bonding region of the rewiring 20. A flat section 12F and a flat section 20F are arranged to surround the bonding region, and the slit S is provided outside the flat section 12.

In providing a slit S for the polyimide resin film 12 at a position outside the bonding region of the rewiring 20 in such a manner, the bonding layer 23 above the slit S, namely, the bonding layer 23 positioned outside the bonding region of the rewiring 20 is provided with a step section 46 having a side surface with an angle close to the taper angle (θ). Thus, as the contact area between the rewiring 20 and the bonding layer 23 further increases, the adhesive force between the rewiring 20 and the bonding layer 23 can be further improved.

The embodiment may be combined with one or plural other embodiments from the embodiments 1 to 6 without departing from the spirit. The rewiring 20 in the embodiment may form the rewiring 20s (refer to FIG. 2), the dummy wiring 50 in foregoing Embodiment 5, the resistance element R, the capacitance element, or the inductance element in Embodiment 6, or the like that is not connected with a lead LE or a wiring. Further, instead of the wiring 25, a solder bump (bump electrode) 21 as that in other embodiments may be connected to the rewiring 20.

The invention developed by the inventors has been described above, based on embodiments, but, the invention is not limited to the embodiments, and various modifications and changes can be made without departing from the spirit of the invention.

For the rewiring 20 in Embodiments 1 to 6, Ni films (first Ni film 16 and second Ni film 17) are employed as the metal films at the upper portion of the CU film 15, but, without being limited to the embodiments, metal films other than Ni films also can be employed as long as they have a function to reduce interdiffusion between the solder bump (bump electrode) 21 and the Cu film 15. Further, the rewiring 20 may be formed from materials with a lower resistance than those of the Cu film 15 and the first Ni film 16.

Further, in Embodiments 2, 3, and 4, the rewiring 20 may form the dummy pattern 50 in Embodiment 5, and the passive elements (the resistance element R, the capacitance element, and the inductance element) in Embodiment 6.

Further, the first layer metal film 20′ and the second layer metal film (second Ni film 17) laminated on it in Embodiments 2, 3, and 4 may form the dummy pattern 50 in Embodiment 5 and the passive elements (resistance element R, capacitance element, and inductance element) in Embodiment 6.

Further, Embodiment 7 may be a semiconductor integrated circuit device applied to IC for a hard disk drive (HDD).

Further, the external connection terminal to be connected to the rewiring 20 is not limited to the solder bump 21 or the wiring 24, and may be a lead terminal by wiring bonding (WB).

The present invention is applicable to a semiconductor integrated circuit device having a rewiring structure, and particularly applicable to a semiconductor integrated circuit device in which an external connection terminal, such as a bump electrode or a bonding wiring, is connected to a first end (land section) of a rewiring formed on the device surface of a semiconductor chip, and an electronic system, such as a mobile electronic device mounting the semiconductor integrated circuit device.

1. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and a second end forming a land section formation region; and
(f) a first insulation film that is formed to cover the rewiring and has a first opening at the upper portion of the land section formation region,
wherein the rewiring includes a first metal film that includes a metal film containing copper as a main component, and a second metal film formed at the upper portion of the first metal film,
wherein the land section formation region is formed such that an area of the second metal film is larger than that of the first metal film, and
wherein the first insulation film is formed directly under the second metal film at an end portion of a land section to which a bump electrode is connected in the land section formation region.

2. The semiconductor integrated circuit device according to claim 1,
wherein the rewiring has a portion where the second metal film is not formed over the first metal film extending from the first electrode pad to the land section formation region.

3. The semiconductor integrated circuit device according to claim 1,
wherein the second metal film has a film thickness larger than that of the first metal film.

4. The semiconductor integrated circuit device according to claim 1,
wherein a rewiring not connected to the bump electrode is formed by the first metal film.

5. The semiconductor integrated circuit device according to claim 1,
wherein a dummy wiring is formed by the first metal film.

6. The semiconductor integrated circuit device according, to claim 1,
wherein at least one of a resistance element, a capacitor, and a capacitance element is formed by the first metal film.

7. The semiconductor integrated circuit device according to claim 1,
wherein the second metal film is formed by a metal film containing nickel as a main component, and the first insulation film is formed by a polyimide resin.

8. The semiconductor integrated circuit device according to claim 1,
wherein between the first metal film and the second metal film, a third metal film lies which has the same area as the first metal film and contains nickel as a main component.

9. The semiconductor integrated circuit device according to claim 1,
wherein the second metal film is formed only at the land section and is not formed at the other portion of the rewiring.

10. The semiconductor integrated circuit device according to claim 1,
wherein a concavo-convex shape is provided at a surface of the land section.

11. An electronic system mounting a semiconductor integrated circuit device according to claim 1.

12. The semiconductor integrated circuit device according to claim 1,
wherein the bump electrode is in contact with a top surface and a side surface of the second metal film.

13. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and a second end forming a land section formation region; and
(f) a first insulation film that is formed to cover the rewiring and has a first opening at the upper portion of the land section formation region,
wherein the rewiring includes a first metal film and a second metal film formed at the upper portion of the first metal film,
wherein the land section formation region is formed such that an area of the second metal film is larger than that of the first metal film,
wherein the first insulation film is formed directly under the second metal film at an end portion of a land section to which a bump electrode is connected in the land section formation region, and
wherein the rewiring has a portion where the second metal film is not formed over the first metal film extending from the first electrode pad to the land section formation region.

14. A semiconductor integrated circuit device, comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and a second end forming a land section formation region; and
(f) a first insulation film that is formed to cover the rewiring and has a first opening at the upper portion of the land section formation region,
wherein the rewiring includes a first metal film and a second metal film formed at the upper portion of the first metal film,
wherein the land section formation region is formed such that an area of the second metal film is larger than that of the first metal film,
wherein the first insulation film is formed directly under the second metal film at an end portion of a land section to which a bump electrode is connected in the land section formation region, and
wherein a rewiring not connected to the bump electrode is formed by the first metal film.

15. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and a second end forming a land section formation region; and
(f) a first insulation film that is formed to cover the rewiring and has a first opening at the upper portion of the land section formation region,
wherein the rewiring includes a first metal film and a second metal film formed at the upper portion of the first metal film,
wherein the land section formation region is formed such that an area of the second metal film is larger than that of the first metal film,
wherein the first insulation film is formed directly under the second metal film at an end portion of a land section to which a bump electrode is connected in the land section formation region, and
wherein a dummy wiring is formed by the first metal film.

16. A semiconductor integrated circuit device, comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad'opening and a second end forming a land section formation region; and
(f) a first insulation film that is formed to cover the rewiring and has a first opening at the upper portion of the land section formation region,
wherein the rewiring includes a first metal film and a second metal film formed at the upper portion of the first metal film,
wherein the land section formation region is formed such that an area of the second metal film is larger than that of the first metal film,
wherein the first insulation film is formed directly under the second metal film at an end portion of a land section to which a bump electrode is connected in the land section formation region, and
wherein at least one of a resistance element, a capacitor, and a capacitance element is formed by the first metal film.

17. A method of manufacturing a semiconductor integrated circuit device, comprising the steps of:
(a) preparing a semiconductor substrate including a plurality of semiconductor elements formed on a device surface, a multi-layer wiring that connects between the semiconductor elements, a protection film that covers the device surface and an upper portion of an uppermost-layer wiring of the multi-layer wiring, and a first electrode pad that is formed by a portion of the uppermost-layer wiring and is exposed from a pad opening formed in the protection film;
(b) forming, at the upper portion of the protection film, a first mask with a first end having the pad opening, and a second end having a first opening that reaches a land section formation region;
(c) forming a first layer metal film at the first opening;
(d) after the step (c), forming a second mask having an opening in the land section formation region;
(e) forming a second layer metal film at the second opening; and
(f) forming a first insulation film that covers the first layer metal film and the second layer metal film,
wherein the land section formation region is formed such that an area of the second metal film is larger than that of the first metal film, and
wherein the first insulation film is formed directly under the second metal film at an end portion of a land section to which a bump electrode is connected in the land section formation region.

18. The method of manufacturing a semiconductor integrated circuit device according to claim 17,
wherein the opening of the second mask does not have an opening over the first layer metal film that extends from the first electrode pad to the land section formation region.

19. The method of manufacturing a semiconductor integrated circuit device according to claim 17,
wherein a film thickness of the first layer metal film is larger than that of the second layer metal film.

20. The method of manufacturing a semiconductor integrated circuit device according to claim 17,
wherein the first layer metal film and the second layer metal film are formed by a plating method.

21. A semiconductor integrated circuit device, comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and a second end forming a land section formation region; and
(f) a first insulation film that is formed to cover the rewiring and has a first opening at the upper portion of the land section formation region,
wherein the land section formation region includes a first metal film and a second metal film formed at the upper portion of the first metal film, and
wherein the rewiring is formed such that the rewiring has a portion where the second metal film is not formed at the upper portion of the first metal film extending from the first electrode pad to the land section formation region.

22. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and a second end forming a land section formation region; and
(f) a first insulation film that is formed to cover the rewiring and has a first opening at the upper portion of the land section formation region,
wherein the rewiring includes a first metal film and a second metal film formed at the upper portion of the first metal film, and
wherein a rewiring not connected to an external connection terminal is formed by the first metal film.

23. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and the other end forming a land section formation region; and
(f) a first insulation film that is formed to cover the rewiring and has a first opening at the upper portion of the land section formation region,
wherein the rewiring includes a first metal film and a second metal film formed at the upper portion of the first metal film, and further has a dummy wiring formed by the first metal film.

24. The semiconductor integrated circuit device according to claim 23,
wherein the dummy wiring is formed in a scribe region.

25. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is exposed from a pad opening formed in the protection film;
(e) a rewiring formed at the upper portion of the protection film and having a first end electrically connected to the first electrode pad through the pad opening and the other end forming a land section formation region; and
(f) a first insulation film that is formed to cover the rewiring and has a first opening at the upper portion of the land section formation region,
wherein the rewiring includes a first metal film and a second metal film formed at the upper portion of the first metal film, and further has at least one of a resistance element, a capacitor, and a capacitance element formed by the first metal film.

26. A semiconductor integrated circuit device comprising:
(a) a semiconductor substrate having a device surface;
(b) a plurality of semiconductor elements formed on the device surface and a multi-layer wiring that connects between the semiconductor elements;
(c) a protection film that covers the device surface and an upper portion of an uppermost layer wiring of the multi-layer wiring;
(d) a first electrode pad that is formed by a portion of the uppermost layer wiring and is formed at the protection film;
(e) a rewiring formed at the upper portion of the protection film and having a first end electrically connected to the first electrode pad through the pad opening and a second end forming a connection region; and
(f) an insulation film formed at the upper portion of the protection film and formed, at a lower portion of the connection region, to have a diameter larger than that of the connection region,
wherein the semiconductor substrate is sealed with resin.
